(19) United States
(12) Patent Application Publication
(10) Pub. No.: US 2026/0334246 A1
(43) Pub. Date: Oct. 22, 2026

(54) SEMICONDUCTOR DEVICE

(71) Applicant: FUJI ELECTRIC CO., LTD., Kawasaki-shi (JP)

(72) Inventors: Sota WATANABE, Matsumoto-city (JP); Shunji TAKENOIRI, Matsumoto-city (JP)

(73) Assignee: FUJI ELECTRIC CO., LTD., Kawasaki-shi (JP)

(21) Appl. No.: 19/578,714

(22) Filed: Mar. 25, 2026

(30) Foreign Application Priority Data
Apr. 17, 2025 (JP) 2025-068215

(51) Int. Cl. H10W 70/20; H10W 74/10; H10W 90/10

(52) U.S. Cl. CPC H10W 70/20; H10W 74/111; H10W 90/10

(57) ABSTRACT

A semiconductor device including a semiconductor package having: a first semiconductor chip including a first electrode and a second electrode on an upper surface thereof; a first encapsulating member encapsulating the first semiconductor chip; a first wiring electrode exposed from an upper surface of the first encapsulating member and connected to an upper surface of the first electrode; and a second wiring electrode exposed from the upper surface of the first encapsulating member and connected to an upper surface of the second electrode.

### CROSS-REFERENCE TO RELATED APPLICATIONS

This application is based upon and claims the benefit of priority of the prior Japanese Patent Application No. 2025-068215, filed on Apr. 17, 2025, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a semiconductor chip and an insulating circuit board, on which the semiconductor chip is provided, and these are sealed with a sealing member (see, for example, International Publication Pamphlet No. WO 2024/018851 and Japanese Laid-open Patent Publication No. 2022-152703). There is also a semiconductor device that includes a semiconductor chip, a sealing member enclosing the semiconductor chip, and a terminal connected to an electrode of the semiconductor chip exposed from the sealing member (see, for example, Japanese Laid-open Patent Publication No. 2021-093454).

### SUMMARY OF THE INVENTION

According to an aspect of the present disclosure, there is provided a semiconductor device, including: a semiconductor package including: a first semiconductor chip including a first electrode and a second electrode on an upper surface thereof; a first encapsulating member encapsulating the first semiconductor chip; a first wiring electrode exposed from an upper surface of the first encapsulating member and connected to an upper surface of the first electrode; and a second wiring electrode exposed from the upper surface of the first encapsulating member and connected to an upper surface of the second electrode.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a perspective view of a semiconductor package according to a first embodiment;

FIG. 2 is a sectional view of the semiconductor package according to the first embodiment;

FIG. 3 is a plan view of the semiconductor package according to the first embodiment;

FIG. 4 is a bottom view of the semiconductor package according to the first embodiment;

FIG. 5 is a plan view of a semiconductor device including the semiconductor package according to the first embodiment;

FIG. 6 is a sectional view of a semiconductor package according to a second embodiment;

FIG. 7 is a bottom view of the semiconductor package according to the second embodiment;

FIG. 8 is a sectional view of a semiconductor device including the semiconductor package according to a first example of the second embodiment;

FIG. 9 is a sectional view of a semiconductor device including the semiconductor package according to a second example of the second embodiment;

FIG. 10 is a plan view of the semiconductor device including the semiconductor package according to the second example of the second embodiment;

FIG. 11 is a side view of a mounting example of the semiconductor device including the semiconductor package according to the second example of the second embodiment;

FIG. 12 is a plan view of a semiconductor package according to a third embodiment;

FIG. 13 is a sectional view of the semiconductor package according to the third embodiment;

FIG. 14 is a plan view of a semiconductor device including the semiconductor package according to the third embodiment;

FIG. 15 is a plan view of another semiconductor package according to the third embodiment;

FIG. 16 is a plan view of a semiconductor package according to a first example of a fourth embodiment;

FIG. 17 is a sectional view of the semiconductor package according to the first example of the fourth embodiment;

FIG. 18 is a bottom view of the semiconductor package according to the first example of the fourth embodiment;

FIG. 19 is a plan view of a semiconductor package according to a second example of the fourth embodiment;

FIG. 20 is a sectional view of the semiconductor package according to the second example of the fourth embodiment;

FIG. 21 is a bottom view of the semiconductor package according to the second example of the fourth embodiment;

FIG. 22 is a sectional view of a semiconductor package according to a fifth embodiment;

FIG. 23 is a plan view of the semiconductor package according to the fifth embodiment;

FIG. 24 is a bottom view of the semiconductor package according to the fifth embodiment;

FIG. 25 is a sectional view of a semiconductor device including the semiconductor package according to the fifth embodiment;

FIG. 26 is a plan view of the semiconductor device including the semiconductor package according to the fifth embodiment; and

FIG. 27 is a side view of a mounting example of the semiconductor device including the semiconductor package according to the fifth embodiment.

### DETAILED DESCRIPTION OF THE INVENTION

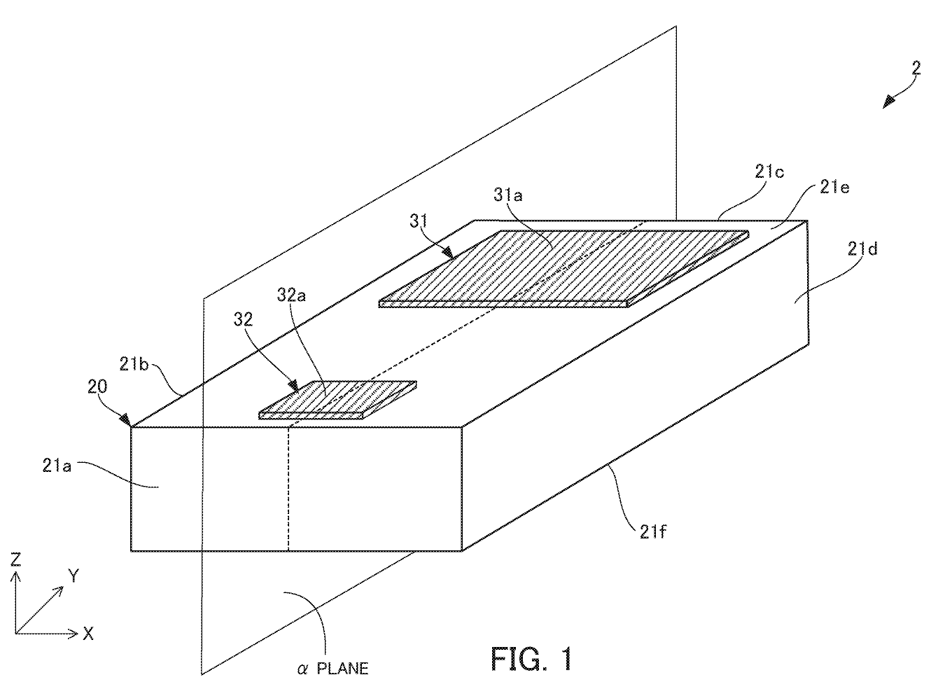

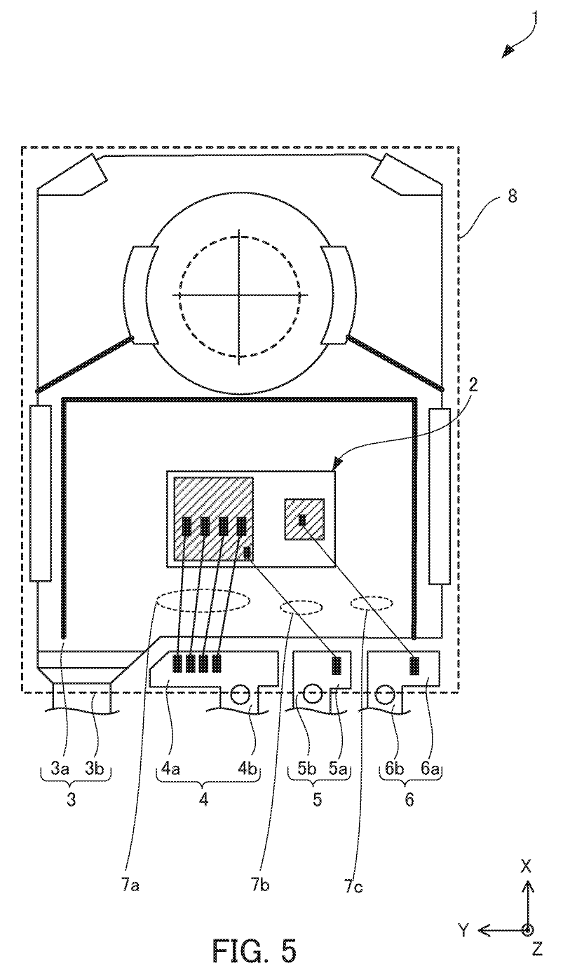

Hereinafter, embodiments will be described with reference to the drawings. In the following description, the term “upper surface” refers to an X-Y plane facing upward (+Z direction) in a semiconductor package 2 of FIG. 1 and a semiconductor device 1 of FIG. 5. Similarly, the term “above” refers to an upward direction (+Z direction) in the semiconductor package 2 of FIG. 1 and the semiconductor device 1 of FIG. 5. The term “lower surface” refers to an X-Y plane facing downward (−Z direction) in the semiconductor package 2 of FIG. 1 and the semiconductor device 1 of FIG. 5. Similarly, the term “below” refers to a downward direction (−Z direction) in the semiconductor package 2 of FIG. 1 and the semiconductor device 1 of FIG. 5. The same directional indications are used in other drawings where appropriate. The terms “upper surface”, “above”, “lower surface”, “below”, and “side surface” are merely used for convenience in describing relative positional relationships, and do not limit the technical concept of the present disclosure. For example, the terms “above” and “below” do not necessarily mean the vertical directions with respect to the ground. That is, the terms “above” and “below” directions are not limited to the gravity direction. The same applies to the other drawings. In addition, in the following description, the term “main component” refers to a component contained in an amount of 80 vol% or more. Further, the expression “substantially the same” is intended to include variations within a range of ±10%. In addition, the terms “perpendicular” and “parallel” are intended to include variations within a range of ±10°.

### First Embodiment

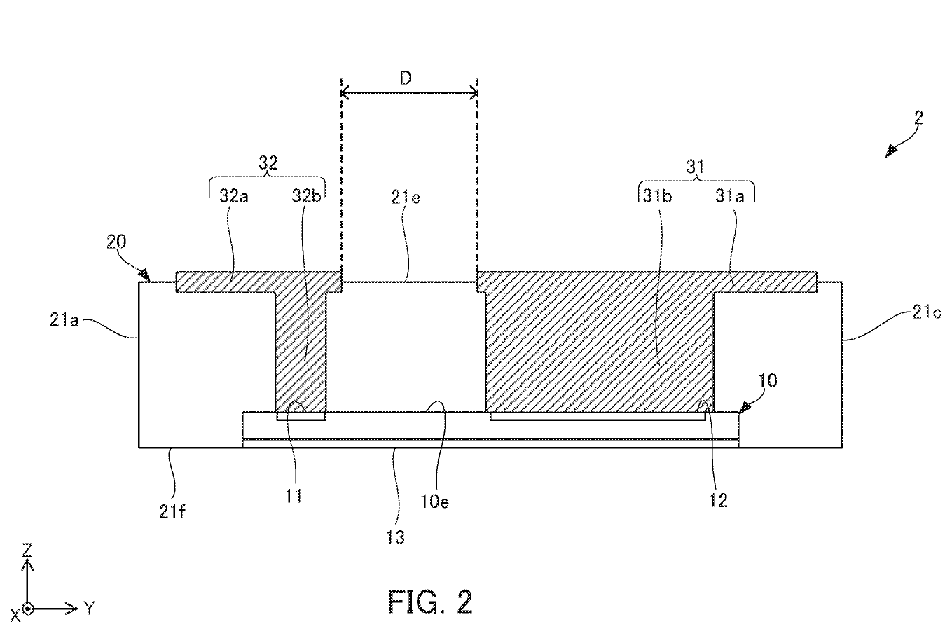

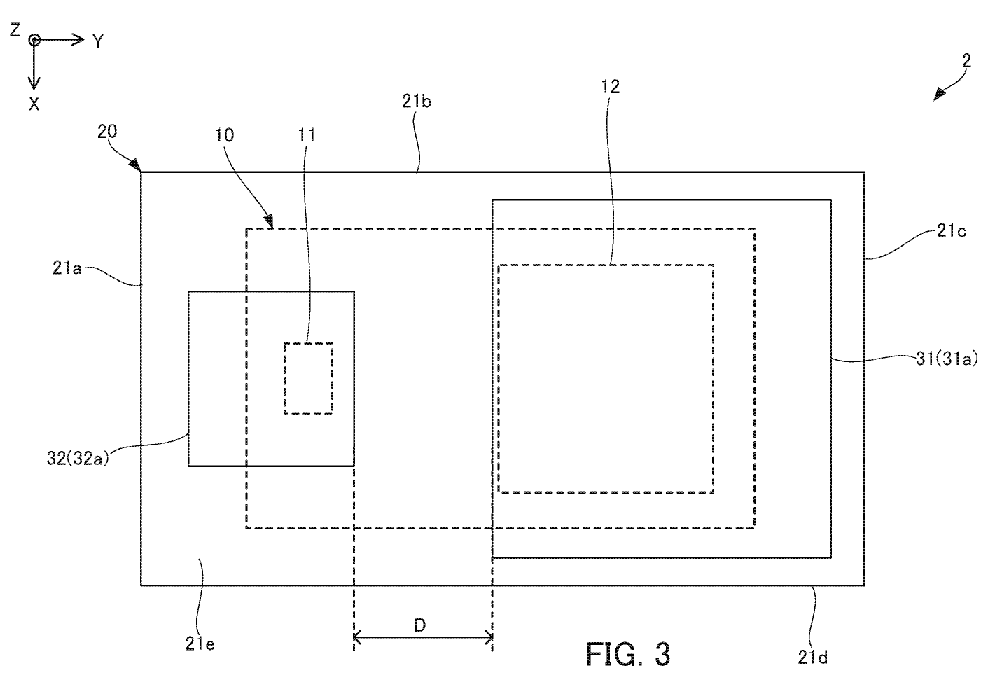

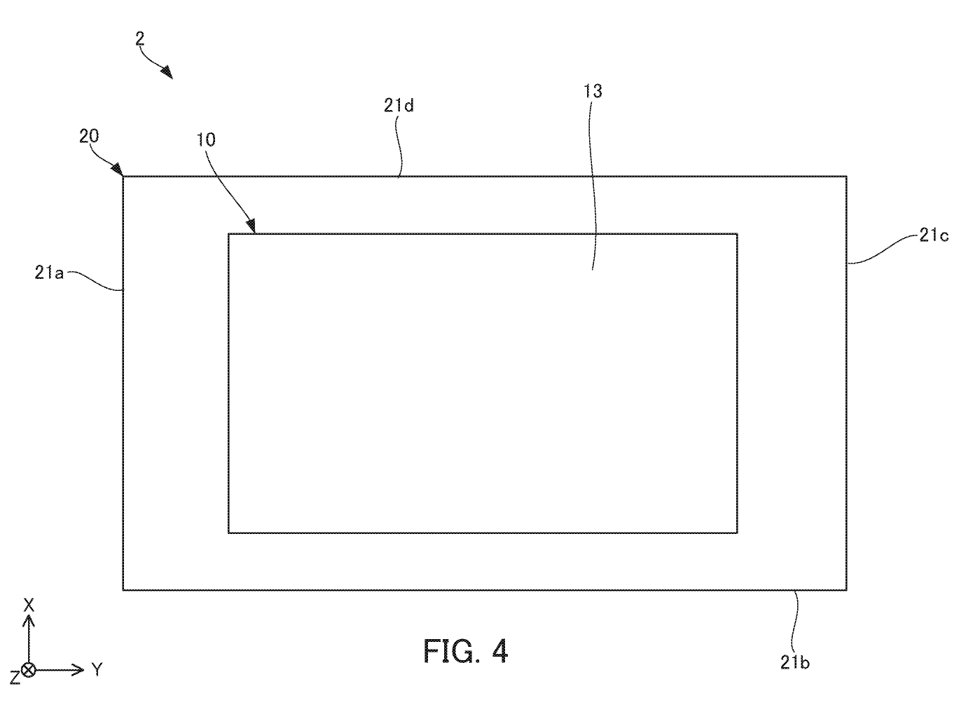

The semiconductor package 2 according to a first embodiment will be described with reference to FIGS. 1-4. FIG. 1 is a perspective view of the semiconductor package according to the first embodiment. FIG. 2 is a sectional view of the semiconductor package according to the first embodiment. FIG. 3 is a plan view of the semiconductor package according to the first embodiment. FIG. 4 is a bottom view of the semiconductor package according to the first embodiment. The sectional view of FIG. 2 is a sectional view of the semiconductor package 2 of FIG. 1 taken along an α-plane, as viewed in the −X direction. The plan view of FIG. 3 is a plan view of a front side (an upper surface 21e of an encapsulating body 20) of the semiconductor package 2 illustrated in FIG. 1. The bottom view of FIG. 4 is a plan view of a back side (a lower surface 21f of the encapsulating body 20) of the semiconductor package 2 illustrated in FIG. 1. In FIG. 3, a semiconductor chip 10, and a control electrode 11 and an output electrode 12 that are included in the semiconductor chip 10 are indicated by broken lines.

The semiconductor package 2 includes the semiconductor chip 10, an output wiring electrode 31, a control wiring electrode 32, and the encapsulating body 20 (encapsulating member) that encapsulates these components. The semiconductor chip 10 may be a power metal-oxide-semiconductor field-effect transistor (MOSFET) made of a material containing silicon carbide as a main component. The semiconductor chip 10 may be made of a material containing gallium nitride as a main component. In the power MOSFET, the body diode may function as a free-wheeling diode (FWD). The semiconductor chip 10 includes the control electrode 11 (gate electrode) (first electrode) and the output electrode 12 (source electrode) (second electrode), which serves as a main electrode, on an upper surface 10e (first upper surface), and the input electrode 13 (drain electrode) (third electrode), which serves as a main electrode, on the entire surface opposite to the upper surface 10e. For example, the upper surface 10e has a rectangular shape in plan view. The control electrode 11 is provided at a position near one short side of the upper surface 10e and around the center of the one short side. The output electrode 12 occupies substantially half of a region of the upper surface 10e near the other short side thereof. The input electrode 13 has a rectangular shape in plan view, similarly to the upper surface 10e.

Alternatively, the semiconductor chip 10 may include a switching element made of a material containing silicon as a main component. The switching element is, for example, a reverse-conducting insulated gate bipolar transistor (RC-IGBT). RC-IGBT is a semiconductor element in which an IGBT and an FWD are configured in inverse-parallel in one chip. The semiconductor chip 10 of this type includes the control electrode 11 (gate electrode) and the output electrode 12 (emitter electrode), which serves as a main electrode, on the upper surface 10e, and the input electrode 13 (collector electrode), which serves as a main electrode, on the side opposite to the upper surface 10e.

The encapsulating body 20 encapsulates the semiconductor chip 10. The encapsulating body 20 has, for example, a cubic shape. The encapsulating body 20 has the upper surface 21e and the lower surface 21f, which have the same rectangular shape and the same area, and side surfaces 21a, 21b, 21c, and 21d sequentially surrounding the four sides of each of the upper surface 21e and the lower surface 21f. The side surfaces 21a, 21b, 21c, and 21d, the upper surface 21e, and the lower surface 21f may be substantially flat.

The upper surface 21e faces the upper surface 10e of the encapsulated semiconductor chip 10 with a gap therebetween, has the same shape as the upper surface 10e, and may be larger in area than the upper surface 10e. On the side opposite to the upper surface 10e, the input electrode 13 of the semiconductor chip 10 is entirely exposed. The side surfaces 21a and 21c extend along the short-side direction of the upper surface 21e and the input electrode 13. The side surfaces 21b and 21d extend along the long-side direction of the upper surface 21e and the input electrode 13. The connections between the side surfaces 21a, 21b, 21c, and 21d may be right-angled, or may be rounded or chamfered. The connections between the upper surface 21e and each of the side surfaces 21a, 21b, 21c, and 21d may also be right-angled, or may be rounded or chamfered. The eight corners of the encapsulating body 20 may also be rounded. The encapsulating body 20 may be made of a thermosetting resin. Examples of the thermosetting resin include an epoxy resin, a phenol resin, a maleimide resin, and a polyester resin. The encapsulating body 20 may further contain a filler. The filler may contain, as a main component, an insulating ceramic material having high thermal conductivity. Examples of such a filler include silicon oxide, aluminum oxide, boron nitride, and aluminum nitride. The content of the filler may be 10% or more and 70% or less by volume with respect to the entire encapsulating body 20.

The output wiring electrode 31 is an example of a second wiring electrode, is exposed from the upper surface 21e of the encapsulating body 20, and is connected to the upper surface of the output electrode 12 of the semiconductor chip 10. The output wiring electrode 31 integrally includes a connection portion 31a and a wiring portion 31b.

The connection portion 31a may have, for example, a flat plate shape, and have a rectangular shape in plan view. The area of the connection portion 31a is preferably larger than that of the output electrode 12 of the semiconductor chip 10 in plan view. The connection portion 31a may be disposed, for example, in a region of the upper surface 21e of the encapsulating body 20 near the other (+Y direction) short side (the side where the output electrode 12 is located) in plan view. In this connection, the connection portion 31a may be disposed to overlap the output electrode 12 in plan view, and may be disposed closer to the other (+Y direction) short side than is the output electrode 12. A lower portion of the connection portion 31a is embedded in the upper surface 21e of the encapsulating body 20. In this case, the upper surface of the connection portion 31a is flush with the upper surface 21e of the encapsulating body 20 or protrudes upward (in +Z direction) beyond the upper surface 21e of the encapsulating body 20. In the first embodiment, the upper surface of the connection portion 31a protrudes upward beyond the upper surface 21e of the encapsulating body 20.

The wiring portion 31b mechanically and electrically connects the lower surface of the connection portion 31a to the upper surface of the output electrode 12. The wiring portion 31b may have, for example, a columnar shape (a circular column, a rectangular column). In this case, the bottom surface of the wiring portion 31b may be substantially the same in area as the output electrode 12. The bottom surface of the wiring portion 31b may be bonded to the output electrode 12 by a bonding member. The bonding member may be, for example, a metal sintered body. Examples of the metal include copper and aluminum. The upper surface of the wiring portion 31b may be integrally connected to the lower surface of the connection portion 31a.

The control wiring electrode 32 is an example of a first wiring electrode, and also integrally includes a connection portion 32a and a wiring portion 32b. The connection portion 32a may have, for example, a flat plate shape, and have a rectangular shape in plan view. The area of the connection portion 32a is preferably larger than that of the control electrode 11 of the semiconductor chip 10 in plan view. The connection portion 32a may be disposed, for example, in a region of the upper surface 21e of the encapsulating body 20 near the one (−Y direction) short side (the side where the control electrode 11 is provided) in plan view. In this connection, the connection portion 32a may be disposed to overlap the control electrode 11 in plan view, and may be closer to the one short side (−Y direction) than is the control electrode 11. A lower portion of the connection portion 32a is embedded in the upper surface 21e of the encapsulating body 20. In this case, the upper surface of the connection portion 32a is flush with the upper surface 21e of the encapsulating body 20 or protrudes upward (in +Z direction) beyond the upper surface 21e of the encapsulating body 20. In the first embodiment, the upper surface of the connection portion 32a protrudes upward beyond the upper surface 21e of the encapsulating body 20. This makes it easy to recognize the bonding positions of wires 7a, 7b, and 7c described later, with a camera during the wire bonding.

The wiring portion 32b mechanically and electrically connects the lower surface of the connection portion 32a to the upper surface of the control electrode 11. The wiring portion 32b may also have, for example, a columnar shape (a circular column, a rectangular column). In this case, the bottom surface of the wiring portion 32b may substantially be the same in area as the control electrode 11. The bottom surface of the wiring portion 32b may be bonded to the control electrode 11 by a bonding member. The bonding member may be, for example, a metal sintered body. Examples of the metal include silver, iron, copper, aluminum, titanium, nickel, tungsten, and molybdenum. The upper surface of the wiring portion 32b may be integrally connected to the lower surface of the connection portion 32a.

The output wiring electrode 31 and the control wiring electrode 32 are made of a material having excellent conductivity. Examples of such a material include copper, aluminum, and an alloy containing at least one of them. The output wiring electrode 31 and the control wiring electrode 32 may be plated with a material having excellent corrosion resistance. Examples of such a material include nickel, a nickel-phosphorus alloy, and a nickel-boron alloy.

A creepage distance D between the connection portion 31a of the output wiring electrode 31 and the connection portion 32a of the control wiring electrode 32 is preferably 0.5 mm or more, more preferably 0.6 mm or more. This ensures reliable insulation between the connection portion 31a of the output wiring electrode 31 and the connection portion 32a of the control wiring electrode 32.

Next, a semiconductor device including the semiconductor package 2 will be described with reference to FIG. 5. FIG. 5 is a plan view of the semiconductor device including the semiconductor package according to the first embodiment. The semiconductor device 1 includes the semiconductor package 2, lead frames 3, 4, 5, and 6, and an encapsulating member 8. In FIG. 5, the encapsulating member 8 is indicated by a broken line.

The lead frames 3, 4, 5, and 6 are made of a material having excellent conductivity. Examples of such a material include copper, aluminum, and an alloy containing at least one of them. The lead frames 3, 4, 5, and 6 may be plated with a material having excellent corrosion resistance. Examples of such a material include nickel, a nickel-phosphorus alloy, and a nickel-boron alloy.

The lead frame 3 is an example of a third external wiring terminal, and integrally includes a die pad 3a and an external connection terminal 3b. The semiconductor package 2 is provided in a substantially central portion of the die pad 3a. The lower surface 21f of the semiconductor package 2 is provided on the die pad 3a by a bonding member (not illustrated). The semiconductor package 2 is disposed so that the output wiring electrode 31 is located on the side where the external connection terminal 3b described later is provided. In the figure, the external connection terminal 3b is integrally connected to the lower end portion of the die pad 3a, at the left end portion thereof, and extends downward. The external connection terminal 3b serves as an external terminal for the input electrode 13 of the semiconductor chip 10 included in the semiconductor package 2.

The bonding member may be solder or a metal sintered body. The solder components constituting the solder include lead-free solder containing a predetermined alloy as a main component. The predetermined alloy contains tin. Such an alloy is, for example, at least one of a tin-silver alloy, a tin-silver-copper alloy, a tin-zinc-bismuth alloy, a tin-copper alloy, a tin-silver-indium-bismuth alloy, and a tin-antimony alloy. Furthermore, such solder components may contain additives. Examples of the additives include nickel, germanium, cobalt, and silicon. Therefore, the solder components include, for example, at least one of silver, zinc, copper, bismuth, indium, and antimony, in addition to tin. Further, the solder components may include, for example, at least one of nickel, germanium, cobalt, and silicon. The metal sintered material is, for example, powder of silver, iron, copper, aluminum, titanium, nickel, tungsten, or molybdenum.

The lead frame 4 is an example of a second external wiring terminal, and is disposed adjacent to the external connection terminal 3b of the lead frame 3 in the −Y direction. The lead frame 4 integrally includes a die pad 4a and an external connection terminal 4b. The die pad 4a is provided below the die pad 3a. The die pad 4a is connected to the connection portion 31a of the output wiring electrode 31 of the semiconductor package 2 via a plurality of wires 7a, which are an example of a second wiring member. In the figure, the external connection terminal 4b is integrally connected to the lower end portion of the die pad 4a, at the right end portion thereof, and extends downward. The external connection terminal 4b serves as an external terminal for the output electrode 12 of the semiconductor chip 10 included in the semiconductor package 2. In the first embodiment, the plurality of wires 7a are used to connect the connection portion 31a of the output wiring electrode 31 to the die pad 4a. For example, a lead frame may be used for this connection.

The lead frame 5 is disposed adjacent to the external connection terminal 4b of the lead frame 4 in the -Y direction. The lead frame 5 integrally includes a die pad 5a and an external connection terminal 5b. The die pad 5a is provided below the die pad 3a. The die pad 5a is connected to the connection portion 31a of the output wiring electrode 31 of the semiconductor package 2 via a wire 7b. In the figure, the external connection terminal 5b is integrally connected to the lower end portion of the die pad 5a, at the left end portion thereof, and extends downward. The external connection terminal 5b serves as an external terminal (auxiliary source terminal) for the output electrode 12 of the semiconductor chip 10 included in the semiconductor package 2.

The lead frame 6 is disposed adjacent to the external connection terminal 5b of the lead frame 5 in the -Y direction. The lead frame 6 is an example of a first external wiring terminal, and integrally includes a die pad 6a and an external connection terminal 6b. The die pad 6a is provided below the die pad 3a. The die pad 6a is connected to the connection portion 32a of the control wiring electrode 32 of the semiconductor package 2 via a wire 7c, which is an example of a first wiring member. In the figure, the external connection terminal 6b is integrally connected to the lower end portion of the die pad 6a, at the left end portion thereof, and extends downward. The external connection terminal 6b serves as an external terminal for the control electrode 11 of the semiconductor chip 10 included in the semiconductor package 2.

The wires 7a, 7b, and 7c may be made of a material containing, for example, gold, silver, copper, aluminum, or an alloy containing at least one of these metals, as a main component. The diameter of the wire 7a is larger than those of the wires 7b and 7c.

The encapsulating member 8 encapsulates the area indicated by the broken line in FIG. 5. That is, the encapsulating member 8 encapsulates the die pads 3a, 4a, 5a, and 6a of the lead frames 3, 4, 5, and 6 and the semiconductor package 2. The encapsulating member 8 also encapsulates portions of the external connection terminals 3b, 4b, 5b, and 6b adjacent to the die pads 3a, 4a, 5a, and 6a, and also encapsulates the entirety of the wires 7a, 7b, and 7c. However, at least a back side of a portion of the die pad 3a, on which portion the semiconductor package 2 is disposed, is exposed from the encapsulating member 8. The encapsulating member 8 may be made of, for example, the same material as the encapsulating body 20.

In recent years, semiconductor chips have been advancing in size reduction. Along with the miniaturization of the semiconductor chips, the output electrodes and the control electrodes of the semiconductor chips are also reduced in size. If such a miniaturized semiconductor chip were mounted on the semiconductor device 1 of FIG. 5, in place of the semiconductor package 2, for example, it would be difficult to reliably connect wires to the miniaturized output electrode and control electrode. This may cause variations in the manufacturing of semiconductor devices. In particular, if the area of the output electrode is limited, the number of wires that are connectable is also limited, which may lead to an inability to obtain sufficient output characteristics.

To address this, the semiconductor package 2 included in the semiconductor device 1 includes the semiconductor chip 10 having the control electrode 11 and the output electrode 12 on the upper surface 10e thereof, the encapsulating body 20 that encapsulates the semiconductor chip 10 and has the upper surface 21e that faces the upper surface 10e, the control wiring electrode 32 exposed from the upper surface 21e of the encapsulating body 20 and connected to the upper surface of the control electrode 11, and the output wiring electrode 31 exposed from the upper surface 21e of the encapsulating body 20 and connected to the upper surface of the output electrode 12. With the use of this semiconductor package 2, the control wiring electrode 32 and the output wiring electrode 31 make it possible to reliably ensure electrical connections to the control electrode 11 and the output electrode 12, even in the case where the semiconductor chip 10 is downsized and the areas of the control electrode 11 and the output electrode 12 are thus limited. That is, it is possible to use a smaller-sized semiconductor chip 10, and also to reduce the manufacturing cost of the semiconductor chip 10. In plan view, the area of the connection portion 31a is larger than that of the output electrode 12 of the semiconductor chip 10. Since the plurality of wires 7a are bonded to the output wiring electrode 31, it is possible to obtain the original resistance-voltage characteristics and rated current, even in the case where the semiconductor chip 10 is miniaturized. Furthermore, in plan view, the area of the connection portion 32a is larger than that of the control electrode 11 of the semiconductor chip 10. Thus, the bonding region of the wire 7c is secured, which enables more reliable bonding.

### Second Embodiment

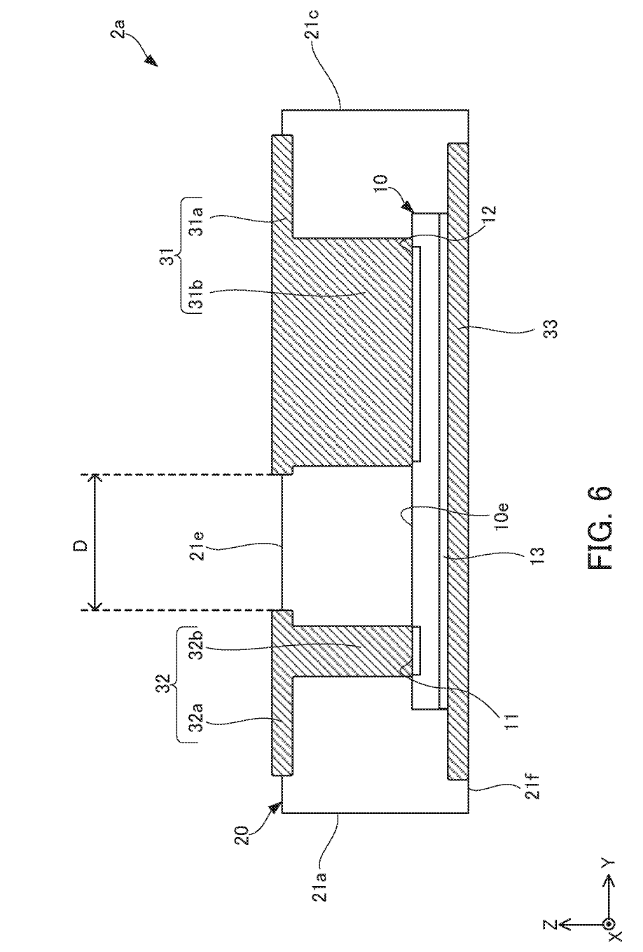

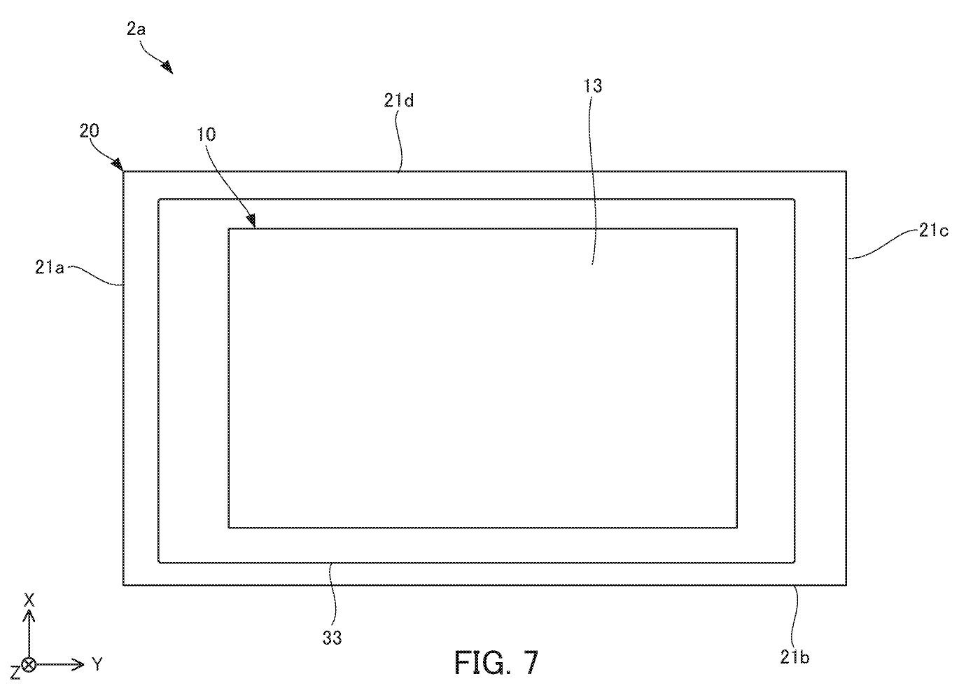

A second embodiment relates to a semiconductor package in which a wiring electrode is additionally provided corresponding to the input electrode 13 of the semiconductor chip 10 in the semiconductor package 2 of the first embodiment. This case will be described with reference to FIGS. 6 and 7.

FIG. 6 is a sectional view of the semiconductor package according to the second embodiment. FIG. 7 is a bottom view of the semiconductor package according to the second embodiment. The sectional view of FIG. 6 is a sectional view taken at a position corresponding to the α-plane of the semiconductor package 2 illustrated in FIG. 1, as viewed in the −X direction. The bottom view of FIG. 7 is a plan view of a back side (the side where the lower surface 21f of the encapsulating body 20 is located) of the semiconductor package 2a illustrated in FIG. 6. Hereinafter, the same components as those of the semiconductor package 2 of the first embodiment are denoted by the same reference numerals, and the description thereof will be omitted or simplified.

In the semiconductor package 2a of the second embodiment, an input wiring electrode 33 is provided on the lower surface of the input electrode 13 of the semiconductor chip 10 of the first embodiment. The input wiring electrode 33 may have, for example, a flat plate shape, and have a rectangular shape in plan view. The area of the input wiring electrode 33 may be larger than that of the input electrode 13 of the semiconductor chip 10 in plan view. In the second embodiment, the area of the input wiring electrode 33 is larger than that of the input electrode 13 of the semiconductor chip 10.

The input wiring electrode 33 is an example of a third wiring electrode, and is disposed on the lower surface 21f of the encapsulating body 20 so as to overlap the input electrode 13 in plan view, for example. The input wiring electrode 33 may be embedded in the lower surface 21f of the encapsulating body 20, and the lower surface of the input wiring electrode 33 may be flush with the lower surface 21f of the encapsulating body 20. Alternatively, the lower surface of the input wiring electrode 33 may protrude downward (in the −Z direction) from the lower surface 21f of the encapsulating body 20. In the second embodiment, the lower surface of the input wiring electrode 33 is flush with the lower surface 21f of the encapsulating body 20.

Also in the second embodiment, a creepage distance D between the control wiring electrode 32 and the output wiring electrode 31 may be the same as that in the first embodiment. Further, in the second embodiment, the creepage distances between the input wiring electrode 33 and each of the control wiring electrode 32 and the output wiring electrode 31 need to be 4mm or more. The thickness of the encapsulating body 20 and the area (the lengths of the long sides and the short sides) of the input wiring electrode 33 are adjusted so that such distances are secured.

In the semiconductor package 2a of the second embodiment, the input wiring electrode 33 is additionally provided on the lower surface 21f, so that the heat dissipation of the semiconductor package 2a is improved. This reduces the risk of a failure in the semiconductor package 2a of the second embodiment, thereby preventing a decrease in reliability.

Next, various examples of a semiconductor device including the semiconductor package 2a of the second embodiment will be described.

### First Example of Second Embodiment

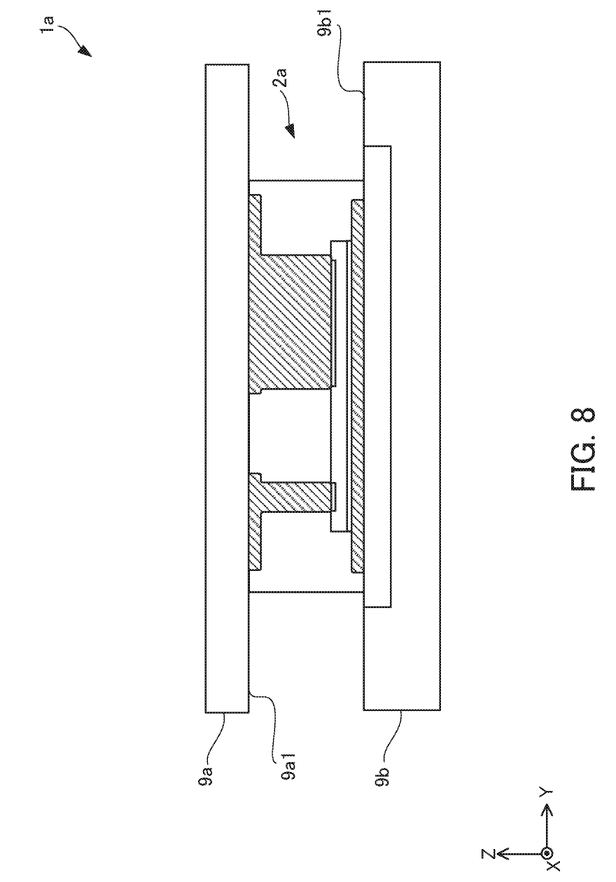

A semiconductor device including the semiconductor package 2a according to a first example of the second embodiment will be described with reference to FIG. 8. FIG. 8 is a sectional view of the semiconductor device including the semiconductor package according to the first example of the second embodiment. The semiconductor device 1a of FIG. 8 may include a cooling unit 9a and a printed substrate 9b together with the semiconductor package 2a.

The cooling unit 9a includes a cooling surface 9a1, and may be, for example, a heat sink, or a cooling device in which a coolant is circulated. The upper surface 21e of the semiconductor package 2a is disposed on the cooling surface 9a1. In this case, the connection portion 31a of the output wiring electrode 31 and the connection portion 32a of the control wiring electrode 32 of the semiconductor package 2a may be flush with the upper surface 21e of the encapsulating body 20.

The printed substrate 9b includes a mounting surface 9b1, and the mounting surface 9b1 may have thereon a circuit pattern layer forming a desired circuit. The lower surface 21f of the semiconductor package 2a is mounted on the mounting surface 9b1 and is electrically connected to a predetermined circuit pattern layer.

In the above semiconductor device 1a, for example, in plan view, the connection portion 31a of the output wiring electrode 31 and the connection portion 32a of the control wiring electrode 32 may be arranged to extend outward from sides of the cooling unit 9a (for example, from the +Y-direction side and the -Y-direction side in FIG. 8, or from the +X-direction side and the -X-direction side in FIG. 8), and the extended portions may be connected to an external device by wiring members. At this time, the connection portion 31a of the output wiring electrode 31 and the connection portion 32a of the control wiring electrode 32 may be insulated from the cooling unit 9a.

Alternatively, the semiconductor device 1a may have the following configuration. For example, the connection portion 31a of the output wiring electrode 31 and the connection portion 32a of the control wiring electrode 32 may be wired within the encapsulating body 20 and connected to predetermined circuit pattern layers formed on the mounting surface 9b1 of the printed substrate 9b. Also in this case, the connection portion 31a of the output wiring electrode 31 and the connection portion 32a of the control wiring electrode 32 may be insulated from the cooling unit 9a.

This configuration allows heat to be dissipated from both the upper surface 21e of the semiconductor package 2a and the input electrode 13, thereby reducing the thermal resistance of the semiconductor package 2a. Although the semiconductor device 1a includes the semiconductor package 2a, the semiconductor device 1a may include the semiconductor package 2. In the case where the semiconductor package 2 is included, the input electrode 13 of the semiconductor package 2 is mounted on the mounting surface 9b1 of the printed substrate 9b.

### Second Example of Second Embodiment

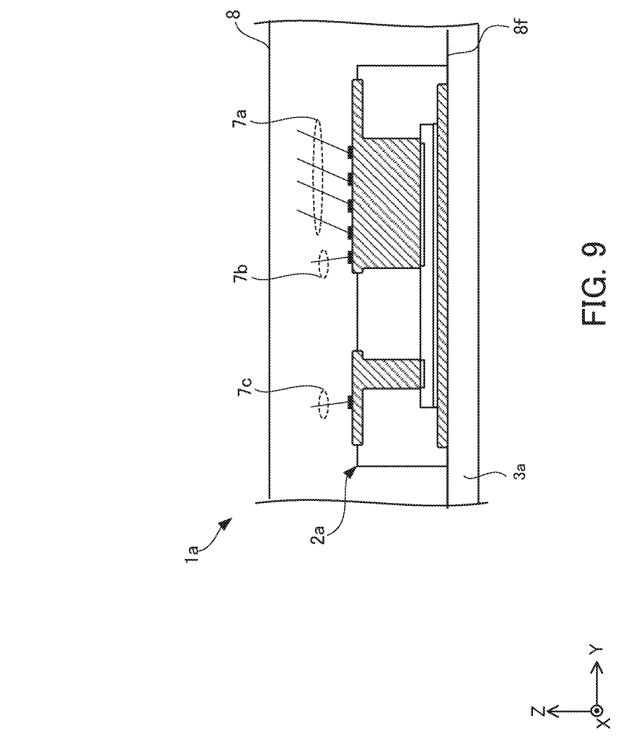

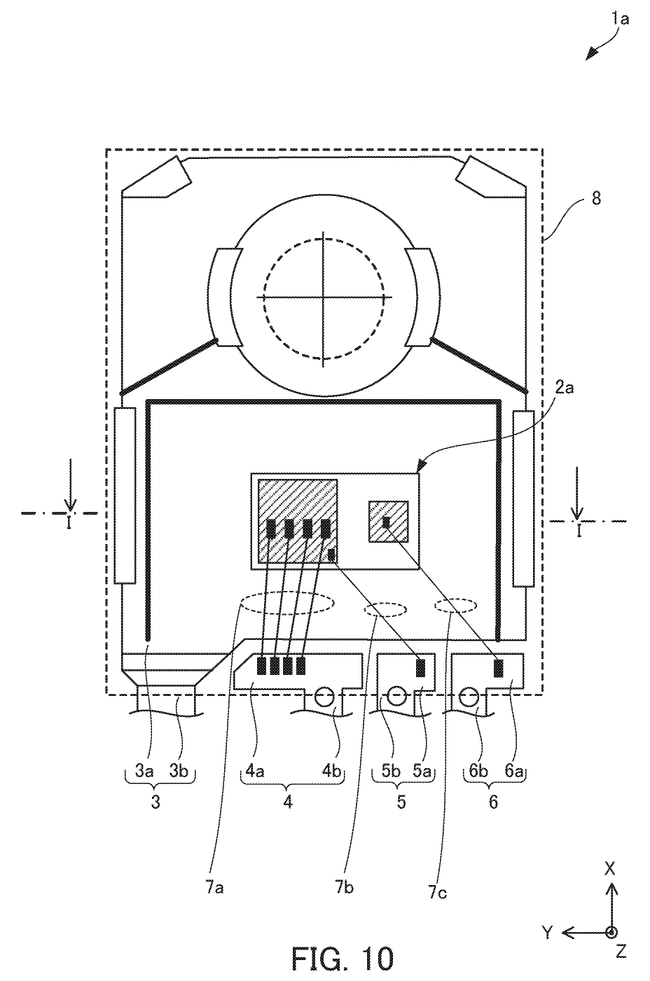

A semiconductor device including the semiconductor package 2a according to a second example of the second embodiment will be described with reference to FIGS. 9 and 10. FIG. 9 is a sectional view of the semiconductor device including the semiconductor package according to the second example of the second embodiment. FIG. 10 is a plan view of the semiconductor device including the semiconductor package according to the second example of the second embodiment. The sectional view of FIG. 9 is a sectional view taken along a dashed-dotted line I-I of FIG. 10. In FIG. 10, the encapsulating member 8 is indicated by a broken line.

The semiconductor device 1a is obtained by applying the semiconductor package 2a to the semiconductor device 1 illustrated in FIG. 5. The semiconductor device 1a also includes the semiconductor package 2a, the lead frames 3, 4, 5, and 6, and the encapsulating member 8 that encapsulates these components. The semiconductor device 1a may have the same configuration as that of FIG. 5 except for the semiconductor package 2a.

The semiconductor package 2a is provided in a substantially central portion of the die pad 3a of the lead frame 3. The input wiring electrode 33 of the semiconductor package 2a is provided on the die pad 3a via a bonding member (not illustrated). The output wiring electrode 31 of the semiconductor package 2a is located on the side where the external connection terminal 3b is provided. The external connection terminal 3b is an external terminal for the input wiring electrode 33 provided on the input electrode 13 of the semiconductor chip 10 included in the semiconductor package 2a. The lead frames 4, 5, and 6, the wires 7a, 7b, and 7c, and the encapsulating member 8 are the same as those described with reference to FIG. 5.

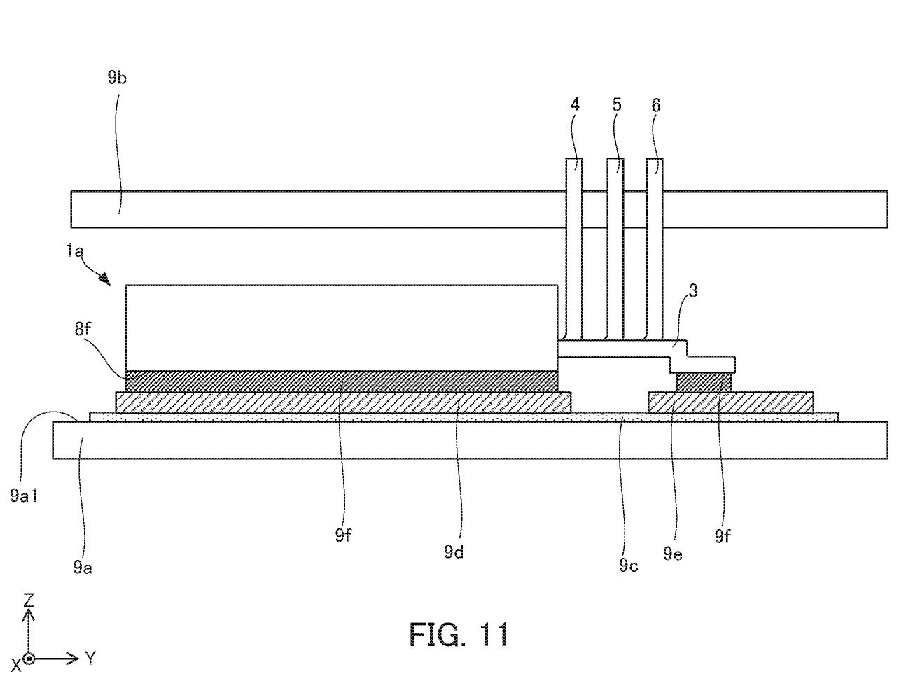

Next, a mounting example in which the above-described semiconductor device 1a is mounted on another external device will be described with reference to FIG. 11. FIG. 11 is a side view of a mounting example of the semiconductor device including the semiconductor package according to the second example of the second embodiment. In the mounting example illustrated in FIG. 11, a part of a device on which the semiconductor device 1a is mounted is illustrated in a side view.

In the semiconductor device 1a, the lead frame 3 extends in the +Y direction, descends in the −Z direction in the middle, and further extends in the +Y direction. The lower surface of the end portion of the lead frame 3 is level with the lower surface 8f of the semiconductor device 1a. The lead frames 4, 5, and 6 also extend in the +Y direction, and bend in the middle to extend in the +Z direction.

Conductive members 9d and 9e are disposed on the cooling surface 9a1 of the cooling unit 9a via an insulating member 9c. The lower surface 8f of the semiconductor device 1a is bonded to the conductive member 9d via a bonding member 9f. The lead frame 3 of the semiconductor device 1a is bonded to the conductive member 9e via the bonding member 9f. That is, the input wiring electrode 33 (not illustrated) of the semiconductor device 1a is electrically connected to the conductive member 9d, and the lead frame 3 is electrically connected to the conductive member 9e. Therefore, the conductive member 9d is connected to the positive electrode of an external power supply, and the conductive member 9e is connected to the negative electrode of the external power supply. The insulating member 9c may be, for example, an insulating sheet. The bonding member 9f may be the above-described solder or a metal sintered body.

The printed substrate 9b is disposed to face the cooling surface 9a1 of the cooling unit 9a. The printed substrate 9b includes a plurality of circuit pattern layers, and is attached to the lead frames 4, 5, and 6 of the semiconductor device 1a to be electrically connected to the lead frames 4, 5, and 6. A control signal is input to the control electrode 11 of the semiconductor chip 10 included in the semiconductor device 1a via the printed substrate 9b and the lead frame 6.

### Third Embodiment

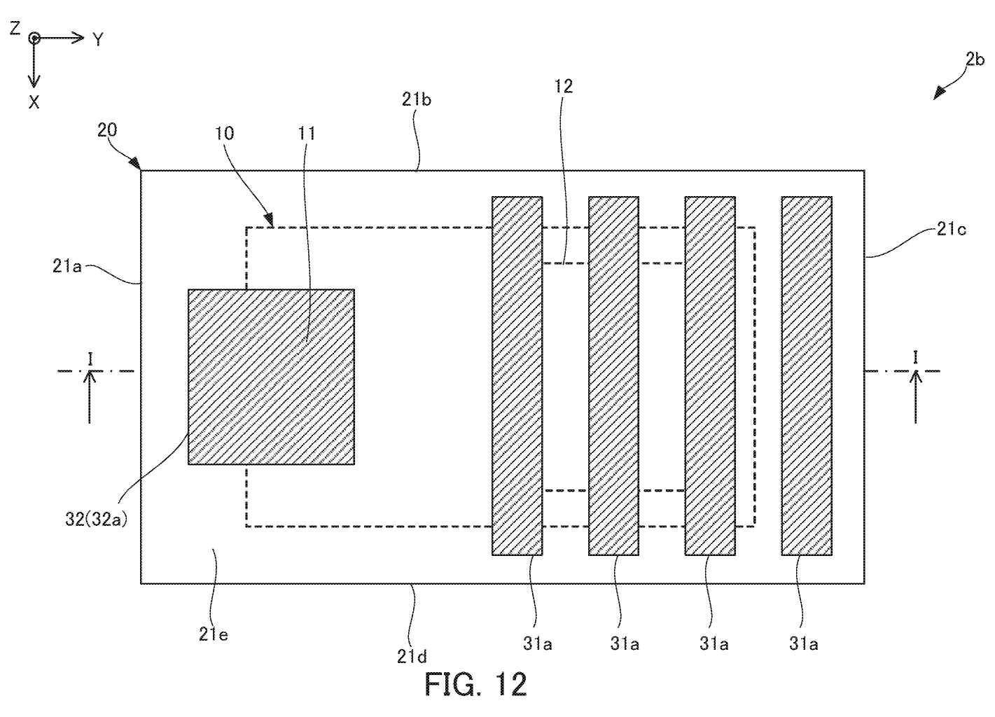

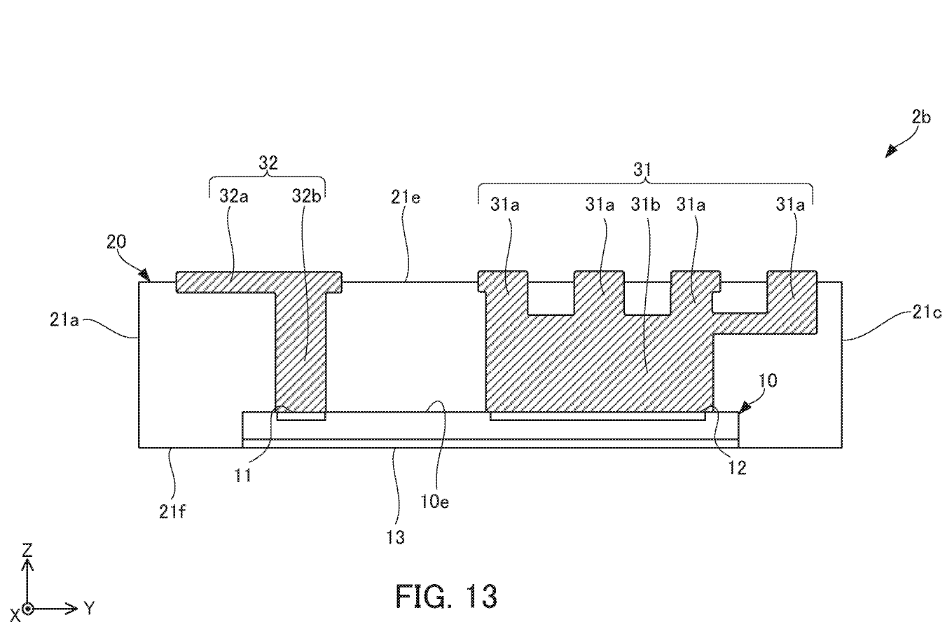

In a third embodiment, another form of the output wiring electrode 31 will be described with reference to FIGS. 12 and 13. FIG. 12 is a plan view of a semiconductor package according to the third embodiment. FIG. 13 is a sectional view of the semiconductor package according to the third embodiment. The sectional view of FIG. 13 is a sectional view taken along a dashed-dotted line I-I of FIG. 12.

The semiconductor package 2b of the third embodiment is different from the semiconductor package 2 of the first embodiment in the shape of the connection portion 31a of the output wiring electrode 31. Other configurations may be the same as those of the semiconductor package 2 of the first embodiment.

The output wiring electrode 31 in the semiconductor package 2b of the third embodiment includes a plurality of connection portions 31a and a wiring portion 31b. The plurality of connection portions 31a branch from the wiring portion 31b and are exposed from the upper surface 21e of the encapsulating body 20. The wiring portion 31b connects the plurality of connection portions 31a to the output electrode 12 of the semiconductor chip 10. As illustrated in FIG. 12, the plurality of branched connection portions 31a form a vertical stripe shape extending in the short-side direction of the encapsulating body 20. The plurality of connection portions 31a are provided along the long-side direction of the encapsulating body 20. The number of connection portions 31a may correspond to the number of wires 7a connected to the lead frame 4, which will be described later.

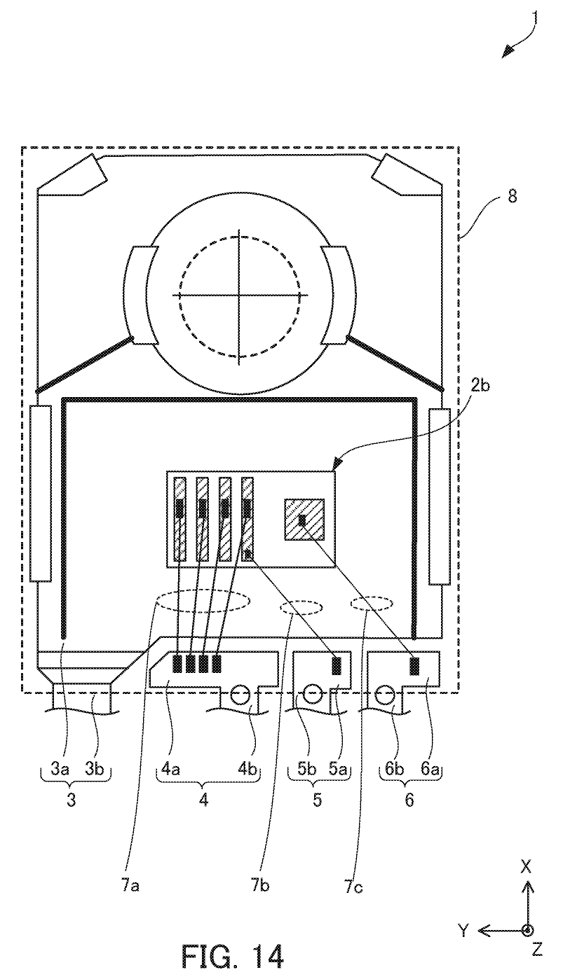

A semiconductor device 1 including the above-described semiconductor package 2b will be described with reference to FIG. 14. FIG. 14 is a plan view of the semiconductor device including the semiconductor package according to the third embodiment. The semiconductor device 1 of the third embodiment is configured by applying the semiconductor package 2b of the third embodiment in place of the semiconductor package 2 of the semiconductor device 1 of the first embodiment. Other configurations are the same as those of the semiconductor device 1 of the first embodiment.

The semiconductor package 2b according to the third embodiment includes connection portions 31a the number of which corresponds to the number of wires 7a. Therefore, the die pad 4a of the lead frame 4 are connected the plurality of connection portions 31a by the wires 7a. In this way, the output wiring electrode 31 secures a bonding region for each wire 7a, so that the wires 7a are reliably bonded. To this end, the width of each connection portion 31a in the ±Y direction may be greater than or equal to the width of the bonding portion of a single wire 7a. In addition, since the connection portions 31a are separated for each wire 7a, the visibility of the connection destinations of the wires 7a is enhanced, and it is possible to reduce the contact between the wires 7a bonded at predetermined intervals.

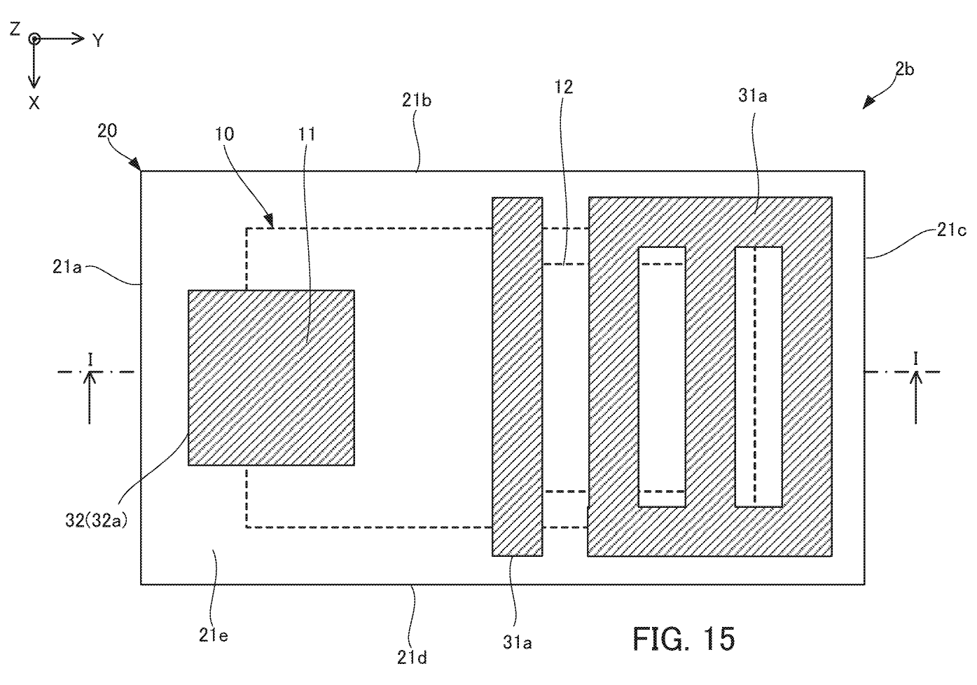

In this connection, the plurality of connection portions 31a of the output wiring electrode 31 are not limited to the vertical stripe shape as long as the visibility of the connection destinations of the wires 7a is improved and the contact between the wires 7a is prevented. For example, a configuration that will be described below with reference to FIG. 15 may be employed.

FIG. 15 is a plan view of another semiconductor package according to the third embodiment. The connection portions 31a illustrated in FIG. 12 are connected at two portions, as seen in the connection portions 31a of the output wiring electrode 31 illustrated in FIG. 15. That is, in the semiconductor package 2b, out of the connection portions 31a provided in the long-side direction as illustrated in FIG. 12, the rightmost connection portion 31a and two connection portions 31a adjacent thereto are connected at their ±X-side end portions. Even in this case, the visibility of the connection destinations of the wires 7a is improved, and the risk of contacts between the wires 7a bonded at predetermined intervals is reduced. In particular, in the case of FIG. 15, since the degree of freedom in selecting the connection destinations of the wires 7a is improved while the wires 7a are spaced apart from each other, it is possible to select connections that reliably prevent the wires 7a from contacting each other.

### Fourth Embodiment

A fourth embodiment provides a case where a plurality of semiconductor chips 10 are included in the semiconductor package 2 of the first embodiment. Hereinafter, two examples will be described regarding the case where two semiconductor chips 10 are included. In the following description, differences from the semiconductor package 2 of the first embodiment will be mainly described. Unless otherwise specified, the configurations of semiconductor packages to be described below are the same as those of the semiconductor package 2 of the first embodiment.

### First Example of Fourth Embodiment

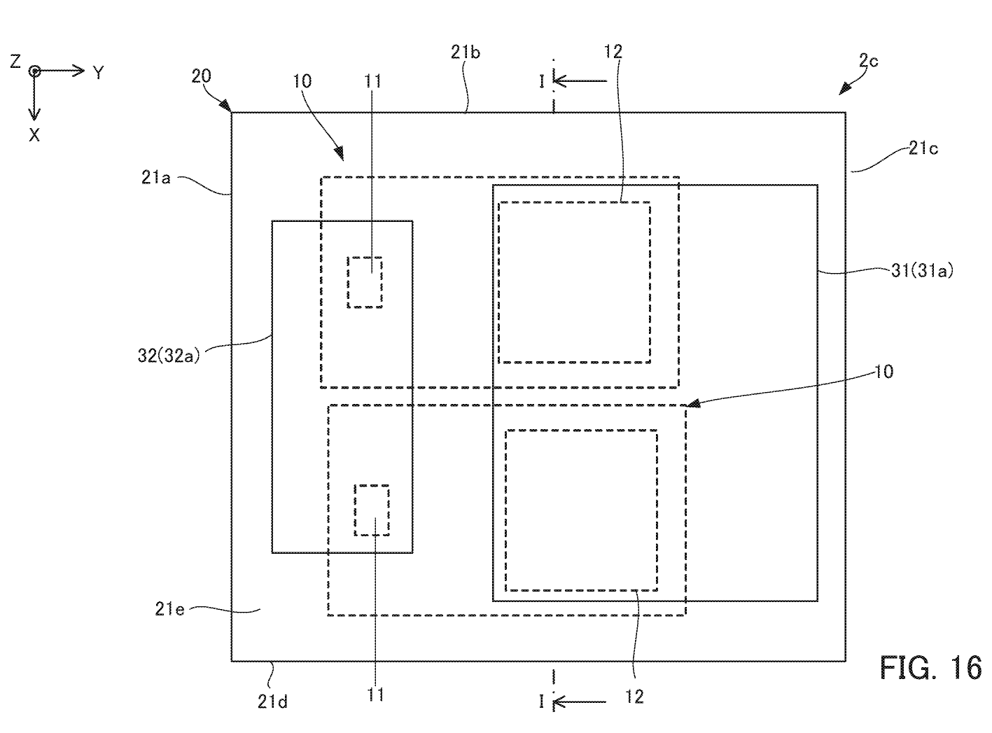

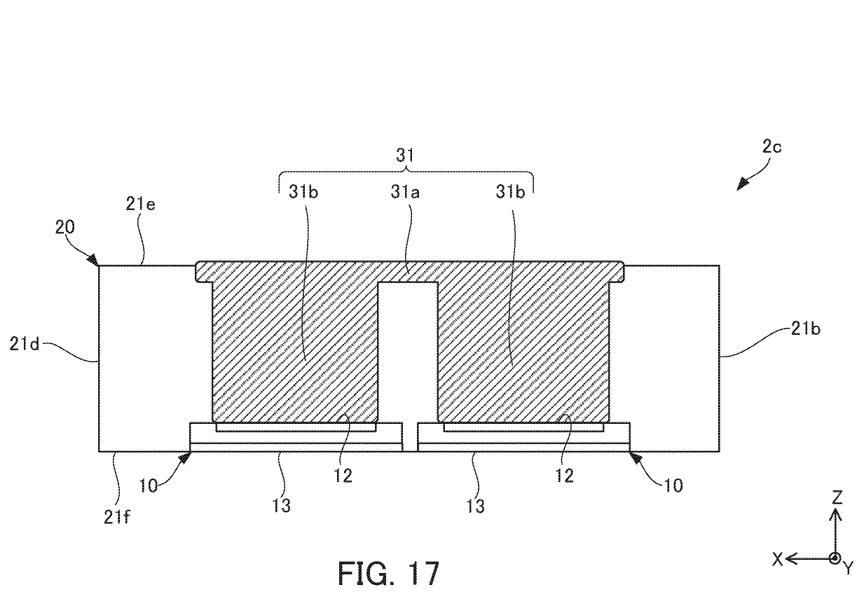

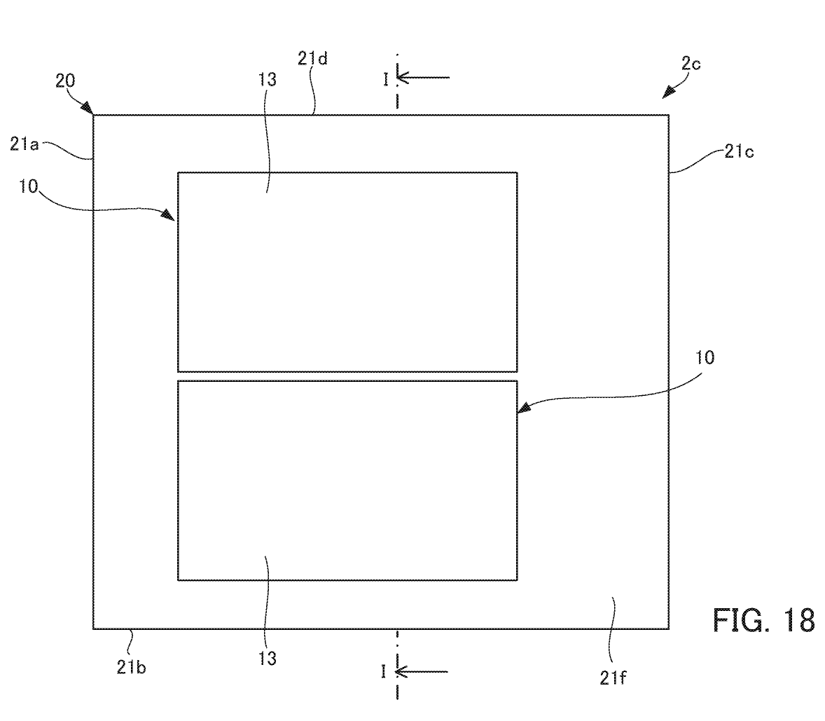

A semiconductor package 2c according to a first example of the fourth embodiment will be described with reference to FIGS. 16 -18. FIG. 16 is a plan view of the semiconductor package according to the first example of the fourth embodiment. FIG. 17 is a sectional view of the semiconductor package according to the first example of the fourth embodiment. FIG. 18 is a bottom view of the semiconductor package according to the first example of the fourth embodiment. The plan view of FIG. 16 is a plan view of the front side (the upper surface 21e of the encapsulating body 20) of the semiconductor package 2c according to the first example of the fourth embodiment. The sectional view of FIG. 17 is a sectional view taken along a dashed-dotted line I-I of FIGS. 16 and 18. The bottom view of FIG. 18 is a plan view of a back side (the lower surface 21f of the encapsulating body 20) of the semiconductor package 2c according to the first example of the fourth embodiment. In FIG. 16, the semiconductor chip 10, and the control electrode 11 and the output electrode 12 that are included in the semiconductor chip 10 are indicated by broken lines.

The semiconductor package 2c of the first example of the fourth embodiment includes two semiconductor chips 10, an output wiring electrode 31, a control wiring electrode 32, and an encapsulating body 20 that encapsulates these components. The semiconductor chip 10 may be the same as that of the first embodiment. Here, the two semiconductor chips 10 are arranged side by side. In this case, the control electrodes 11 and the output electrodes 12 of the two semiconductor chips 10 are adjacent to each other.

The output wiring electrode 31 is exposed from the upper surface 21e of the encapsulating body 20 and is connected to the upper surfaces of the output electrodes 12 of the two semiconductor chips 10. The output wiring electrode 31 integrally includes a connection portion 31a and two wiring portions 31b (a first wiring portion and a second wiring portion).

The connection portion 31a may have, for example, a flat plate shape and a rectangular shape in plan view. The area of the connection portion 31a may be larger than the area of the output electrodes 12 of the two semiconductor chips 10 arranged side by side in plan view. The connection portion 31a may be disposed, for example, near the other side (+Y-direction side) of the upper surface 21e of the encapsulating body 20 in plan view. In this connection, the connection portion 31a may be disposed to overlap the two output electrodes 12 in plan view, and may be closer to the other side (+Y-direction side) than are the two output electrodes 12. In the present embodiment, as an example, the connection portion 31a extends in the +Y direction beyond the two semiconductor chips 10. The area and shape of the connection portion 31a may be appropriately selected according to a desired design.

The two wiring portions 31b (the first wiring portion and the second wiring portion) connect the lower surface of the connection portion 31a to the output electrodes 12 of the two semiconductor chips 10, respectively. The two wiring portions 31b branch from the connection portion 31a and are connected to the output electrodes 12 of the two semiconductor chips 10.

The control wiring electrode 32 also integrally includes a connection portion 32a and two wiring portions 32b. The connection portion 32a may have, for example, a flat plate shape and a rectangular shape in plan view. The area of the connection portion 32a may be larger than the area of the control electrodes 11 of the two semiconductor chips 10 arranged side by side. The connection portion 32a may be disposed, for example, near the one side (−Y-direction side) of the upper surface 21e of the encapsulating body 20 in plan view. In this connection, the connection portion 32a may be disposed to overlap the two control electrodes 11 in plan view, and may be closer to the one side (−Y-direction side) than are the two control electrodes 11. In the present embodiment, as an example, the connection portion 32a extends in the −Y direction beyond the two semiconductor chips 10. The area and shape of the connection portion 32a may be appropriately selected according to a desired design. Although a sectional view of the control wiring electrode 32 is omitted, the control wiring electrode 32 may be configured in the same manner as the output wiring electrode 31 of FIG. 17, and the two wiring portions 32b may be connected to the control electrodes 11 of the two semiconductor chips 10.

The input electrodes 13 of the two semiconductor chips 10 encapsulated in the encapsulating body 20 are exposed from the lower surface 21f of the encapsulating body 20, and the two input electrodes 13 are flush with the lower surface 21f of the encapsulating body 20.

The semiconductor package 2c of the first example of the fourth embodiment may also be disposed in the semiconductor device 1 of FIG. 5 in the same manner as in the first embodiment. Also in this case, the control wiring electrode 32 and the output wiring electrode 31 make it possible to reliably ensure electrical connections to the control electrodes 11 and the output electrodes 12 of the two semiconductor chips 10. Since it is possible to bond the plurality of wires 7a to the output wiring electrode 31, the original resistance-voltage characteristics and rated current are obtained even in the case where the semiconductor chip 10 is miniaturized. In addition, inside the semiconductor package 2c, the control wiring electrode 32 is connected to the respective control electrodes 11 of the plurality of semiconductor chips 10. Similarly, the output wiring electrode 31 is connected to the respective output electrodes 12 of the plurality of semiconductor chips 10. Thus, for example, inductance may be suppressed, compared to the case where a plurality of semiconductor devices 1 of FIG. 5 are connected in parallel.

### Second Example of Fourth Embodiment

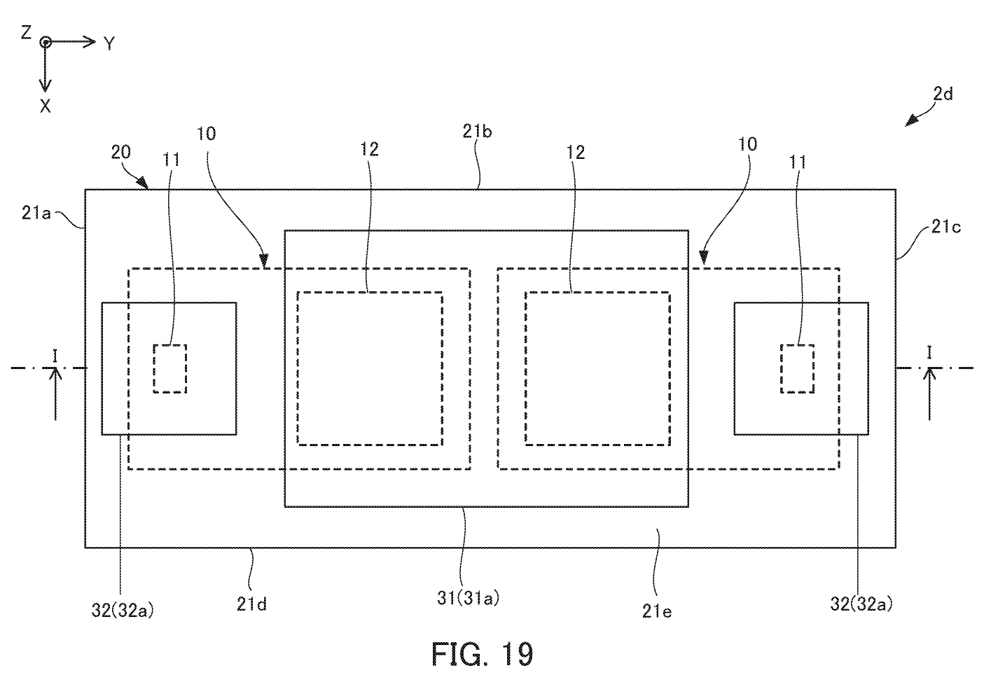

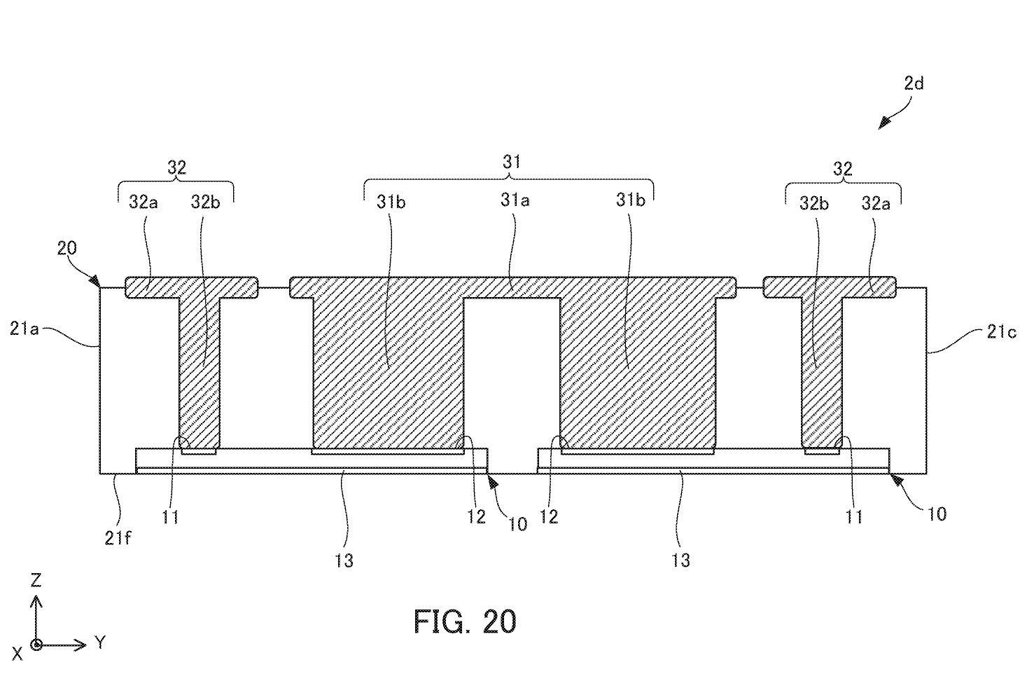

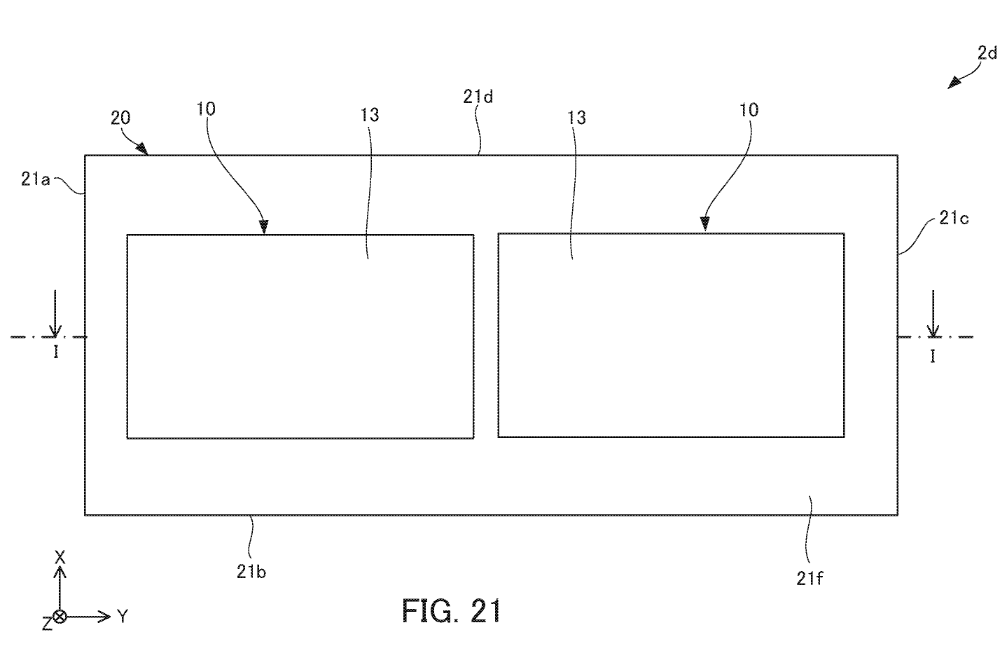

A semiconductor package 2d according to a second example of the fourth embodiment will be described with reference to FIGS. 19-21. FIG. 19 is a plan view of a semiconductor package according to the second example of the fourth embodiment. FIG. 20 is a sectional view of the semiconductor package according to the second example of the fourth embodiment. FIG. 21 is a bottom view of the semiconductor package according to the second example of the fourth embodiment. The plan view of FIG. 19 is a plan view of a front side (the upper surface 21e of the encapsulating body 20) of the semiconductor package 2d according to the second example of the fourth embodiment. The sectional view of FIG. 20 is a sectional view taken along a dashed-dotted line I-I of FIGS. 19 and 21. The bottom view of FIG. 21 is a plan view of a back side (the lower surface 21f of the encapsulating body 20) of the semiconductor package 2d according to the second example of the fourth embodiment. In FIG. 19, the semiconductor chip 10, and the control electrode 11 and the output electrode 12 that are included in the semiconductor chip 10 are indicated by broken lines.

The semiconductor package 2d of the second example of the fourth embodiment includes two semiconductor chips 10, an output wiring electrode 31, control wiring electrodes 32, and an encapsulating body 20 that encapsulates these components. Each semiconductor chip 10 may be the same as that of the first embodiment. In this example, the two semiconductor chips 10 are arranged side by side such that their output electrodes 12 face each other and the control electrodes 11 face opposite sides in plan view.

The output wiring electrode 31 is exposed from the upper surface 21e of the encapsulating body 20 and is connected to the upper surfaces of the output electrodes 12 of the two semiconductor chips 10. The output wiring electrode 31 integrally includes a connection portion 31a and two wiring portions 31b.

The connection portion 31a may have, for example, a flat plate shape and a rectangular shape in plan view. The area of the connection portion 31a may be larger than the area of the output electrodes 12 of the two semiconductor chips 10 arranged side by side in plan view. The connection portion 31a may be disposed, for example, at the center of the upper surface 21e of the encapsulating body 20 in plan view. In this connection, the connection portion 31a may be disposed to overlap the two output electrodes 12 in plan view. The area and shape of the connection portion 31a may be appropriately selected according to a desired design.

Each control wiring electrode 32 also integrally includes a connection portion 32a and a wiring portion 32b. Each connection portion 32a may have, for example, a flat plate shape and a rectangular shape in plan view. Similarly to the first embodiment, the area of the connection portion 32a may be larger than the area of the control electrode 11 of the corresponding semiconductor chip 10. The connection portions 32a may be disposed, for example, near both short sides (±Y-direction sides) of the upper surface 21e of the encapsulating body 20 in plan view. The connection portions 32a may be disposed to overlap the corresponding control electrodes 11 in plan view.

The input electrodes 13 of the two semiconductor chips 10 encapsulated in the encapsulating body 20 are exposed on the lower surface 21f of the encapsulating body 20, and the two input electrodes 13 are flush with the lower surface 21f of the encapsulating body 20.

The semiconductor package 2d of the second example of the fourth embodiment may also be disposed in the semiconductor device 1a of FIG. 8 in the same manner as in the second embodiment. In this case, the input wiring electrode 33 may be attached to the input electrodes 13 of the two semiconductor chips 10 on the lower surface 21f of the semiconductor package 2d.

### Fifth Embodiment

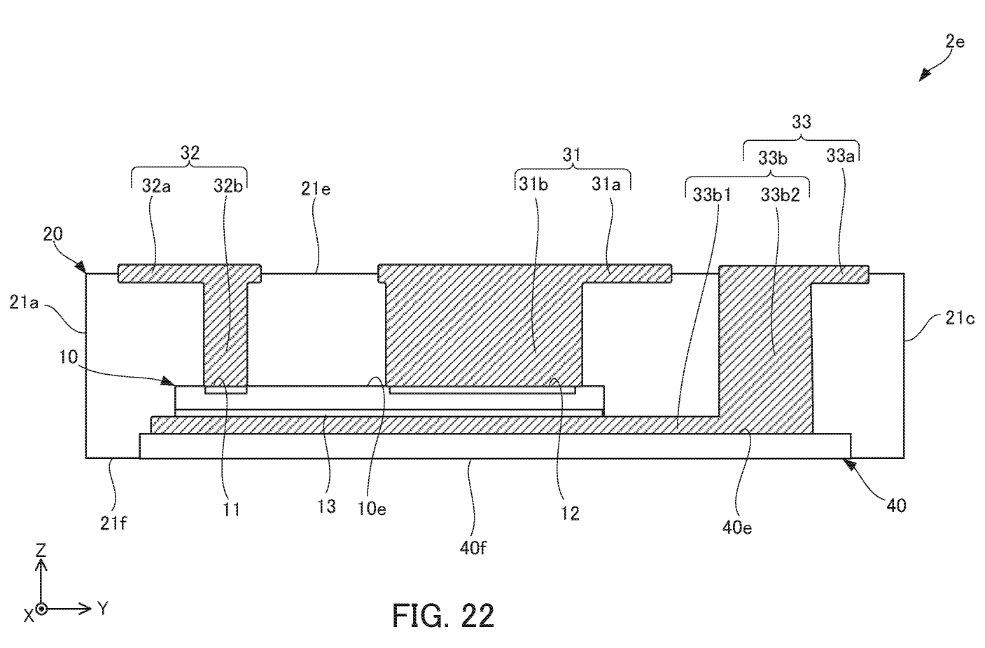

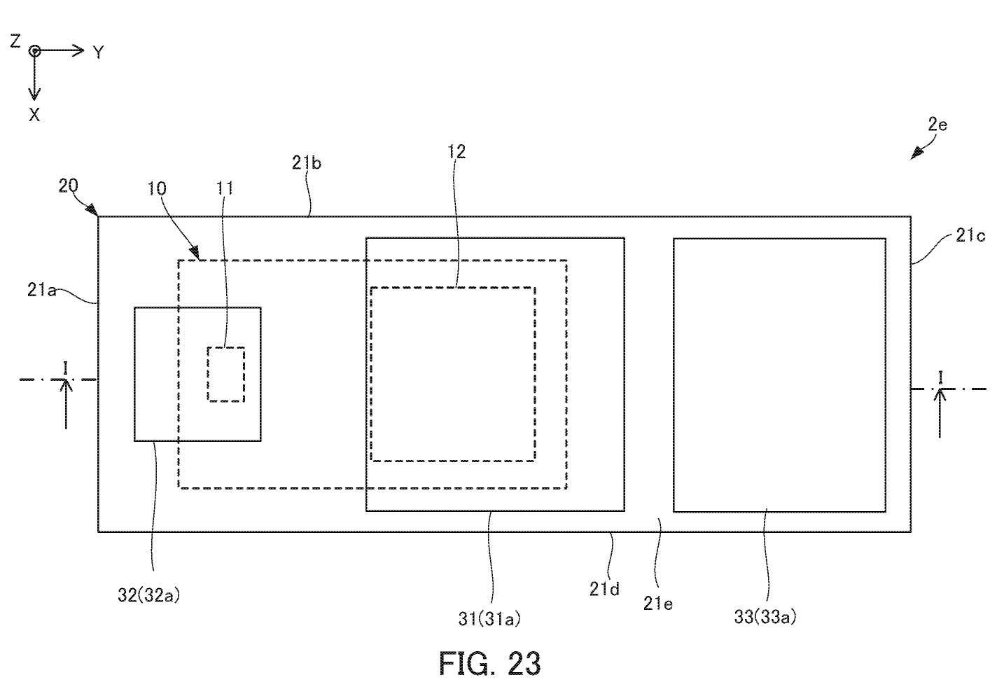

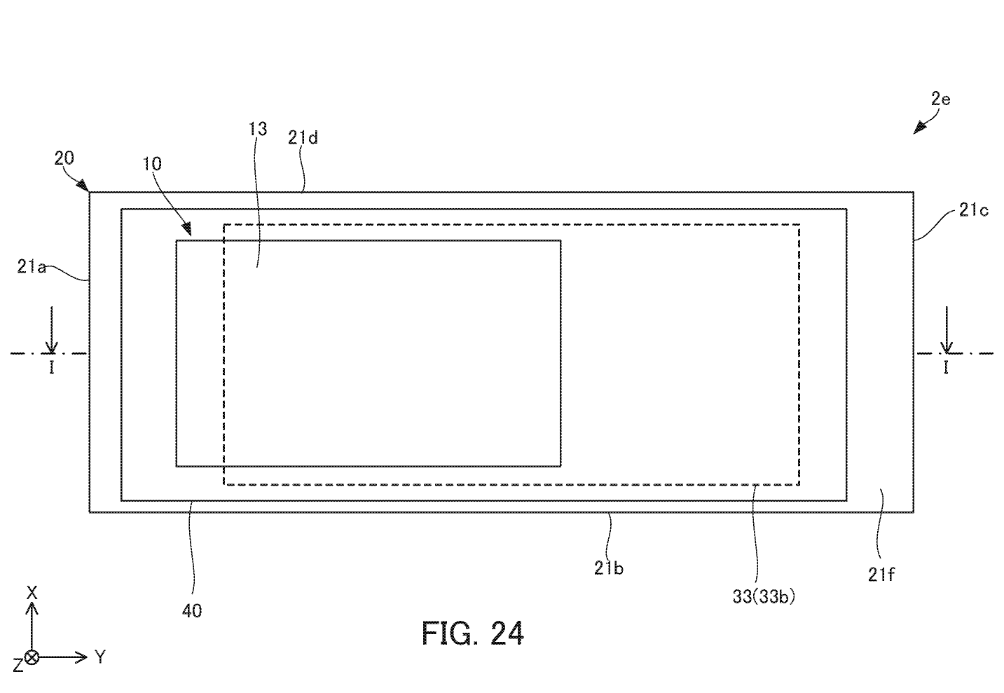

A fifth embodiment provides a case where an input wiring electrode, which is connected to the input electrode 13 of the semiconductor chip 10 in the semiconductor package 2 of the first embodiment, is provided on the upper surface 21e of the encapsulating body 20. A semiconductor package 2e in this case will be described with reference to FIGS. 22-24. FIG. 22 is a sectional view of the semiconductor package according to the fifth embodiment. FIG. 23 is a plan view of the semiconductor package according to the fifth embodiment. FIG. 24 is a bottom view of the semiconductor package according to the fifth embodiment. The sectional view of FIG. 22 is a sectional view taken along a dashed-dotted line I-I of FIGS. 23 and 24. The plan view of FIG. 23 is a plan view of a front side (the upper surface 21e of the encapsulating body 20) of the semiconductor package 2e illustrated in FIG. 22. The bottom view of FIG. 24 is a plan view of a back side (the lower surface 21f of the encapsulating body 20) of the semiconductor package 2e illustrated in FIG. 22. In FIGS. 23 and 24, the semiconductor chip 10, and the control electrode 11, the output electrode 12, and the input electrode 13, which are included in the semiconductor chip 10, and the input wiring electrode 33 are indicated by broken lines.

The semiconductor package 2e includes the semiconductor chip 10, the output wiring electrode 31, the control wiring electrode 32, an input wiring electrode 33, an insulating layer 40, and the encapsulating body 20 that encapsulates these components. The semiconductor chip 10, the output wiring electrode 31, and the control wiring electrode 32 are the same as those described in the first embodiment. The output wiring electrode 31 and the control wiring electrode 32 are provided on the semiconductor chip 10 as in the first embodiment.

The input wiring electrode 33 is exposed from the upper surface 21e of the encapsulating body 20 and is connected to the input electrode 13 of the semiconductor chip 10. The input wiring electrode 33 is made of the same material as the output wiring electrode 31 and the control wiring electrode 32. The input wiring electrode 33 integrally includes a connection portion 33a and a wiring portion 33b.

The connection portion 33a may have, for example, a flat plate shape and a rectangular shape in plan view. The area of the connection portion 33a may be, for example, approximately the same as that of the connection portion 31a of the output wiring electrode 31 in plan view. For example, the connection portion 33a may be disposed adjacent to the connection portion 31a of the output wiring electrode 31 in the +Y direction in plan view. Alternatively, the connection portion 33a may be disposed, for example, adjacent to the connection portion 32a of the control wiring electrode 32 in the −Y direction according to a desired design. A lower portion of the connection portion 33a is embedded in the upper surface 21e of the encapsulating body 20. In this case, the upper surface of the connection portion 33a is flush with the upper surface 21e of the encapsulating body 20 or protrudes upward (+Z direction) from the upper surface 21e of the encapsulating body 20. In the fifth embodiment, the upper surface of the connection portion 33a protrudes upward from the upper surface 21e of the encapsulating body 20.

The wiring portion 33b connects the lower surface of the connection portion 33a to the input electrode 13. The wiring portion 33b integrally includes a bottom portion 33b1 and a rising portion 33b2. The bottom portion 33b1 has a flat plate shape and has a rectangular shape in plan view. The bottom surface 10f of the semiconductor chip 10 is disposed on the bottom portion 33b1, and the input electrode 13 is bonded to the bottom portion 33b1 by the above-described bonding member. The area of the bottom portion 33b1 may be larger than the area of the semiconductor chip 10 in plan view. The semiconductor chip 10 is disposed on the bottom portion 33b1, and one end portion of the bottom portion 33b1 extends in the +Y direction. The extending direction of the bottom portion 33b1 depends on the arrangement position of the connection portion 33a. The rising portion 33b2 may have a columnar shape (for example, a circular column or a rectangular column). The rising portion 33b2 is integrally connected to the one end portion of the bottom portion 33b1, extends in the +Z direction, and is integrally connected to the lower surface of the connection portion 33a.

The insulating layer 40 includes an upper surface 40e having a rectangular shape in plan view and a lower surface 40f opposite to the upper surface 40e and having the same shape as the upper surface 40e. The area of the insulating layer 40 is larger than that of the bottom portion 33b1 of the input wiring electrode 33 in plan view. The bottom portion 33b1 of the wiring portion 33b included in the input wiring electrode 33 is disposed on the upper surface 40e of the insulating layer 40. The insulating layer 40 may be an insulating plate made of a material containing ceramics as a main component. Examples of the material of the main component constituting the ceramics include aluminum oxide, aluminum nitride, and silicon nitride. The insulating layer 40 is encapsulated by the encapsulating body 20, with the lower surface 40f of the insulating layer 40 exposed from the lower surface 21f of the encapsulating body 20. The lower surface 40f of the insulating layer 40 is flush with the lower surface 21f of the encapsulating body 20.

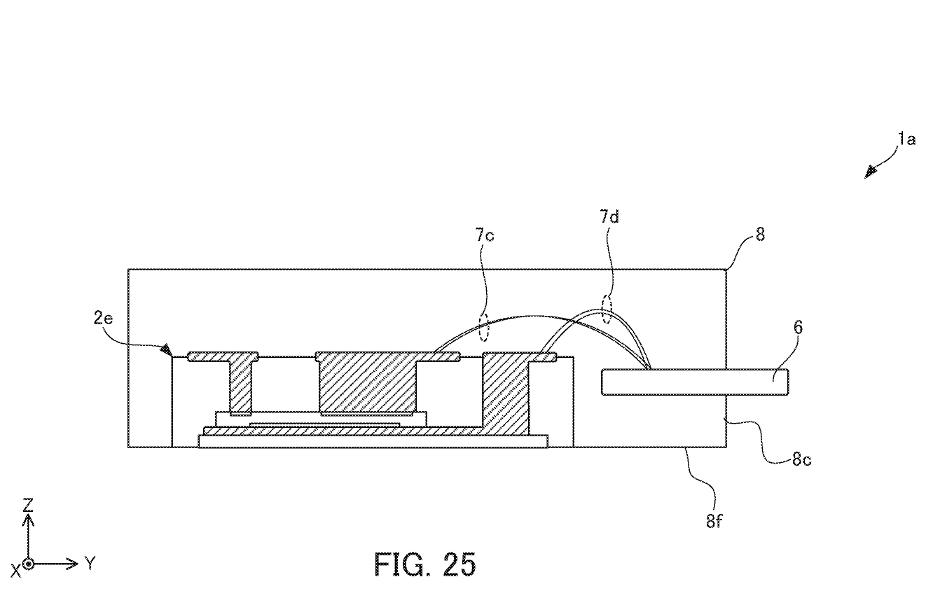

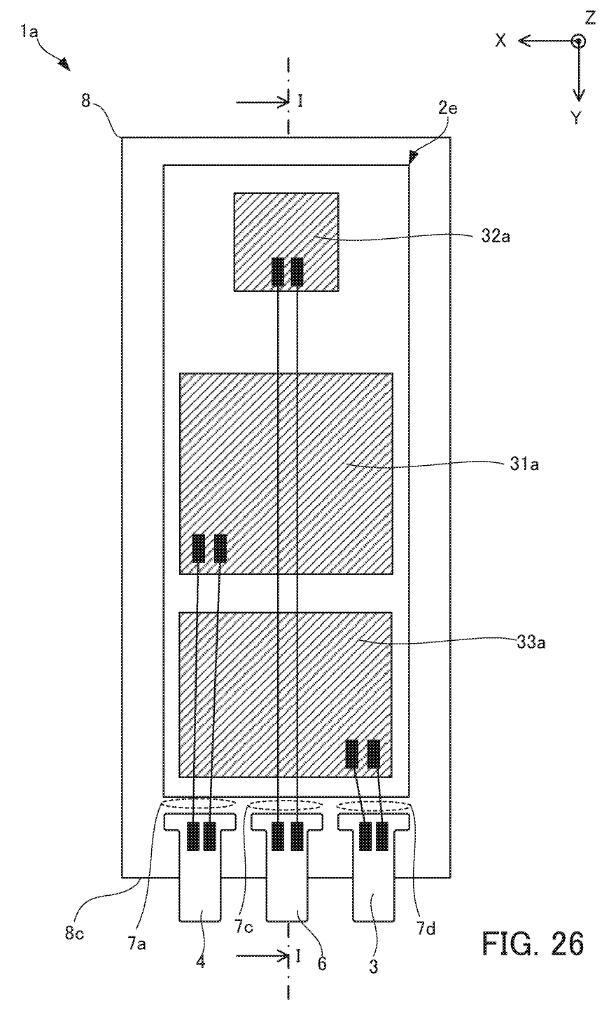

Next, a semiconductor device including the semiconductor package 2e will be described with reference to FIGS. 25 and 26. FIG. 25 is a sectional view of the semiconductor device including the semiconductor package according to the fifth embodiment. FIG. 26 is a plan view of the semiconductor device including the semiconductor package according to the fifth embodiment. The sectional view of FIG. 25 is a sectional view taken along a dashed-dotted line I-I of FIG. 26. FIG. 26 is a plan view of the semiconductor device 1a in a transparent manner.

The semiconductor device 1a includes the semiconductor package 2e of FIGS. 22 - 24, the lead frames 4, 6, and 3, and the encapsulating member 8 that encapsulates these components. The semiconductor package 2e is entirely encapsulated by the encapsulating member 8. In this connection, the lower surface 40f of the insulating layer 40 of the semiconductor package 2e is exposed from the lower surface 8f of the encapsulating member 8 and is flush with the lower surface 8f.

For example, the lead frames 4, 6, and 3 face the side surface 21c of the semiconductor package 2e and are disposed at a lower position than the upper surface 21e of the semiconductor package 2e. The lead frames 4, 6, and 3 are encapsulated in the encapsulating member 8 together with the semiconductor package 2e, and extend outward (in +Y direction) from the side surface 8c facing the side surface 21c of the semiconductor package 2e. The lengths of the extended portions of the lead frames 4, 6, and 3 outside the encapsulating member 8 may be appropriately selected according to a desired design.

The lead frames 4, 6, and 3 are electrically connected to the connection portion 31a of the output wiring electrode 31, the connection portion 32a of the control wiring electrode 32, and the connection portion 33a of the input wiring electrode 33 in the semiconductor package 2a via wires 7a, 7c, and 7d, respectively. Here, the wires 7a, 7c, and 7d are examples of the second, first, and third wiring members. The wiring members are not limited to the wires 7a, 7c, and 7d, and may be a lead frame or a ribbon.

Therefore, the lead frame 4 is an external terminal for the output electrode 12 of the semiconductor chip 10 included in the semiconductor package 2e via the output wiring electrode 31. The lead frame 6 is an external terminal for the control electrode 11 of the semiconductor chip 10 included in the semiconductor package 2e via the control wiring electrode 32. The lead frame 3 is an external terminal for the input electrode 13 of the semiconductor chip 10 included in the semiconductor package 2e via the input wiring electrode 33.

The semiconductor device 1a may include an auxiliary source lead frame in addition to the output, control, and input lead frames 4, 6, and 3. In this case, these four lead frames may be arranged side by side in the ±X direction.

The encapsulating member 8 includes the side surface 8c and the lower surface 8f, and encapsulates the semiconductor package 2e and the lead frames 4, 6, and 3 as described above. The lower surface 40f of the insulating layer 40 of the semiconductor package 2e is exposed from the lower surface 8f of the encapsulating member 8, and is flush with the lower surface 8f of the encapsulating member 8. The side surface 8c of the encapsulating member 8 faces the side surface 21c of the semiconductor package 2e, and the lead frames 4, 6, and 3 extend outward therefrom. The encapsulating member 8 may be made of, for example, the same material as the encapsulating body 20 included in the semiconductor package 2e illustrated in FIGS. 22 - 24.

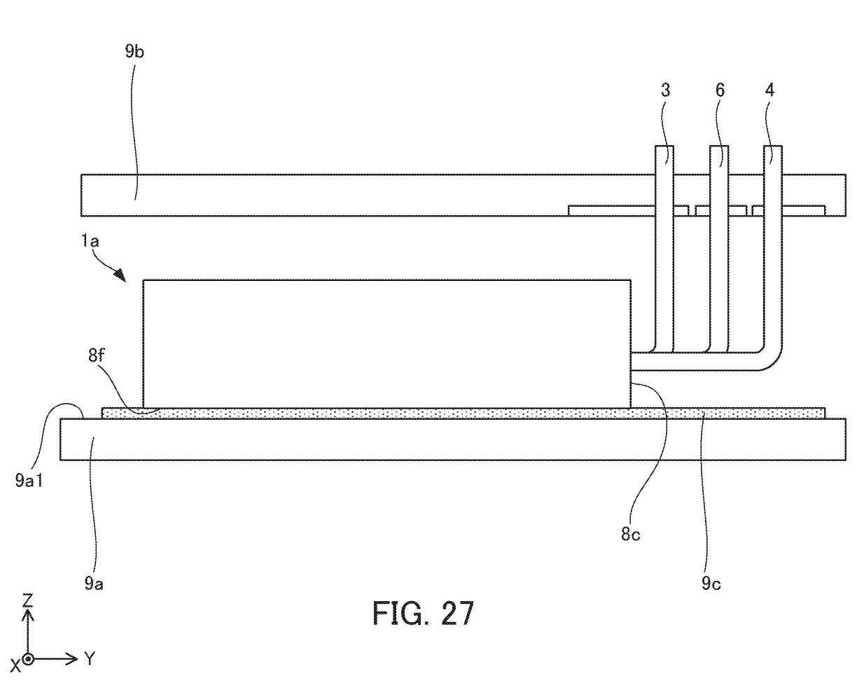

Next, a mounting example in which the above-described semiconductor device 1a is mounted on another external device will be described with reference to FIG. 27. FIG. 27 is a side view of a mounting example of a semiconductor device including the semiconductor package according to the fifth embodiment. In the mounting example illustrated in FIG. 27, a part of a device on which the semiconductor device 1a is mounted is 1illustrated in a side view.

In the semiconductor device 1a, the lead frames 4, 6, and 3 extend in the +Y direction, and bend in the middle to extend in the +Z direction. The bent portions of the lead frames 4, 6, and 3 are closer to the semiconductor device 1a in the order of the lead frames 3, 6, and 4.

The lower surface 8f of the semiconductor device 1a is disposed on the cooling surface 9a1 of the cooling unit 9a via the insulating member 9c. The printed substrate 9b is disposed to face the cooling surface 9a1 of the cooling unit 9a. The printed substrate 9b includes a plurality of circuit pattern layers, and is attached to the lead frames 3, 6, and 4 of the semiconductor device 1a to be electrically connected to the lead frames 3, 6, and 4. A control signal is input to the control electrode 11 of the semiconductor chip 10 included in the semiconductor device 1a via the printed substrate 9b and the lead frame 6. An input current is input to the input electrode 13 of the semiconductor chip 10 included in the semiconductor device 1a via the printed substrate 9b and the lead frame 3. An output current from the output electrode 12 of the semiconductor chip 10 included in the semiconductor device 1a is output to the printed substrate 9b via the lead frame 4.

The disclosed techniques make it possible to reliably secure electrical connection to the semiconductor chip.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor package including:
a first semiconductor chip including a first electrode and a second electrode on an upper surface thereof;
a first encapsulating member encapsulating the first semiconductor chip;
a first wiring electrode exposed from an upper surface of the first encapsulating member and connected to an upper surface of the first electrode; and
a second wiring electrode exposed from the upper surface of the first encapsulating member and connected to an upper surface of the second electrode.

2. The semiconductor device according to claim 1, wherein an area of the upper surface of the first encapsulating member is larger than an area of the upper surface of the first semiconductor chip in a plan view of the semiconductor device.

3. The semiconductor device according to claim 1, wherein
the first wiring electrode is located above the first electrode, and has an area larger than an area of the first electrode in a plan view of the semiconductor device, and
the second wiring electrode is located above the second electrode, and has an area larger than an area of the second electrode in the plan view.

4. The semiconductor device according to claim 3, wherein the first wiring electrode and the second wiring electrode are separated from each other by 0.5 mm or more in the plan view.

5. The semiconductor device according to claim 1, wherein
the first semiconductor chip further includes a third electrode on a side thereof opposite to a side on which the first and second electrodes are formed,
the first encapsulating member has a lower surface opposite to the upper surface thereof, and
the third electrode of the first semiconductor chip is exposed from the lower surface of the first encapsulating member.

6. The semiconductor device according to claim 5, further comprising:
a first external wiring terminal electrically connected to the first wiring electrode of the semiconductor package via a first wiring member;
a second external wiring terminal electrically connected to the second wiring electrode of the semiconductor package via a second wiring member;
a third external wiring terminal including an arrangement portion on which the semiconductor package is disposed; and
a second encapsulating member encapsulating the semiconductor package together with the arrangement portion of the third external wiring terminal.

7. The semiconductor device according to claim 1, wherein
the first semiconductor chip further includes a third electrode on a side thereof opposite to a side on which the first and second electrodes are formed,
the first encapsulating member has a lower surface facing the upper surface thereof, and
the semiconductor package further includes a third wiring electrode exposed from the lower surface of the first encapsulating member and connected to a lower surface of the third electrode.

8. The semiconductor device according to claim 7, further comprising:
a first external wiring terminal electrically connected to the first wiring electrode of the semiconductor package via a first wiring member;
a second external wiring terminal electrically connected to the second wiring electrode of the semiconductor package via a second wiring member;
a third external wiring terminal including an arrangement portion on which the semiconductor package is disposed; and
a second encapsulating member encapsulating the semiconductor package together with the arrangement portion of the third external wiring terminal.

9. The semiconductor device according to claim 1, wherein
the second wiring electrode includes
a plurality of connection portions exposed from the upper surface of the first encapsulating member, and
a wiring portion connecting the plurality of connection portions to the upper surface of the second electrode of the first semiconductor chip, and
the plurality of connection portions are branched from the wiring portion.

10. The semiconductor device according to claim 9, wherein the plurality of connection portions are arranged in one direction.

11. The semiconductor device according to claim 9, further comprising:
a first external wiring terminal electrically connected to the first wiring electrode of the semiconductor package via a first wiring member;
a second external wiring terminal electrically connected to the plurality of connection portions of the second wiring electrode of the semiconductor package via a plurality of second wiring members, respectively;
a third external wiring terminal including an arrangement portion on which the semiconductor package is disposed; and
a second encapsulating member encapsulating the semiconductor package together with the arrangement portion of the third external wiring terminal.

12. The semiconductor device according to claim 1, further comprising:
a second semiconductor chip including a first electrode thereof and a second electrode thereof on an upper surface thereof,
wherein the first encapsulating member encapsulates the first semiconductor chip and the second semiconductor chip, and
wherein the second wiring electrode includes
a connection portion exposed from the upper surface of the first encapsulating member,
a first wiring portion connecting the upper surface of the second electrode of the first semiconductor chip to the connection portion, and
a second wiring portion connecting an upper surface of the second electrode of the second semiconductor chip to the connection portion.

13. The semiconductor device according to claim 12, wherein the first wiring electrode is connected to the upper surface of the first electrode of the first semiconductor chip and an upper surface of the first electrode of the second semiconductor chip.

14. The semiconductor device according to claim 1, wherein
the first semiconductor chip further includes a third electrode on a side thereof opposite to a side on which the first and second electrodes are formed, and
the semiconductor package further includes a third wiring electrode exposed from the upper surface of the first encapsulating member and connected to a lower surface of the third electrode.

15. The semiconductor device according to claim 14, further comprising:
a first external wiring terminal electrically connected to the first wiring electrode of the semiconductor package via a first wiring member;
a second external wiring terminal electrically connected to the second wiring electrode of the semiconductor package via a second wiring member;
a third external wiring terminal electrically connected to the third wiring electrode of the semiconductor package via a third wiring member; and
a second encapsulating member encapsulating the semiconductor package, a portion of the first external wiring terminal to which the first wiring electrode is connected, a portion of the second external wiring terminal to which the second wiring electrode is connected, and a portion of the third external wiring terminal to which the third wiring electrode is connected.
